(19) United States
(12) Patent Application Publication
(10) Pub. No.: US 2009/0170227 A1
(43) Pub. Date: Jul. 2, 2009

(54) MASK AND CONTAINER AND MANUFACTURING

(75) Inventors: Shunpei YAMAZAKI, Tokyo (JP); Junichiro SAKATA, Atsugi (JP); Hideaki KUWABARA, Isehara (JP)

Correspondence Address: NIXON PEABODY, LLP, 401 9TH STREET, NW, SUITE 900, WASHINGTON, DC, 20004-2128, US

(73) Assignee: Semiconductor Energy Laboratory Co., Ltd., Atsugi-shi (JP)

(21) Appl. No.: 12/362,461

(22) Filed: Jan. 29, 2009

Related U.S. Application Data
(62) Division of application No. 10/820,130, filed on Apr. 8, 2004.

(30) Foreign Application Priority Data
Apr. 10, 2003 (JP) 2003-106139

(51) Int. Cl. H01L 33/00; H01L 21/50

(52) U.S. Cl. 438/26; 257/E33.058; 257/E21.499; 257/E33.06

(57) ABSTRACT

The present invention provides a large mask with a high mask accuracy for conducting selective deposition on a substrate with a large surface area. In accordance with the present invention, the mask body is fixed in a fixing position disposed on a line passing through a thermal expansion center in the width of the mask frame. Further, in accordance with the present invention, the substrate and mask body are fixed and deposition is carried out by moving the deposition source in the X direction or Y direction. A method comprising moving the deposition source in the X direction or Y direction is suitable for deposition on large substrates.

### DETAILED DESCRIPTION OF THE INVENTION

1. Technical Field to which the Invention Belongs

The present invention relates to a film forming apparatus employed for forming a film of a material capable of forming a film by deposition (referred to hereinbelow as a deposition material) and a production apparatus comprising such a film forming apparatus. In particular, the present invention relates to a mask employed for deposition in which a film is formed by evaporating a deposition material from a deposition source provided opposite to a substrate, a container for accommodating the deposition material, and a production apparatus.

2. Prior Art

Light-emitting elements using organic compounds featuring small thickness and weight, fast response, DC low-voltage drive, and the like, as light-emitting substances have been expected to find application in flat panel displays of the next generation. In particular, display devices in which light emitting elements are disposed as a matrix have been considered to be superior to the conventional liquid-crystal displays in that they have a wide viewing angle and excellent visibility.

As for the light emission mechanism of light-emitting elements, it is thought that electrons introduced from a cathode and holes introduced from an anode recombinate in an organic compound layer at the light-emitting center and form molecular excitons under the effect of the voltage applied to a pair of electrodes sandwiching a layer containing the organic compound and energy is then released and light is emitted when the molecular excitons return to a ground state. Singlet excitation and triplet excitation are known as excited states and light emission is considered to be possible via any excited state.

In light-emitting devices formed by arranging such light-emitting elements as a matrix, drive methods such as a passive matrix drive (simple matrix type) and active matrix drive (active matrix type) can be used. However, when the pixel density is increased, the active matrix type, in which a switch is provided for each pixel (or 1 dot) is considered to be advantageous because a low-voltage drive is possible.

Further, a layer comprising an organic compound has a multilayer structure, typically in the form of “hole transfer layer/light-emitting layer/electron transfer layer”. EL materials forming an EL layer are generally classified into low-molecular (monomer) materials and high-molecular (polymer) materials, and low-molecular materials are employed to form films in deposition apparatuses.

The conventional deposition apparatuses have a substrate disposed in a substrate holder and comprise a crucible (or a deposition boat) having an EL material, that is, a deposition material, introduced therein, a shutter preventing the sublimated EL material from rising, and a heater for heating the EL material located inside the crucible. The EL material heated with the heater is sublimated and forms a film on the rotating substrate. In order to conduct uniform film formation in this process, the distance between the substrate and the crucible is set to 1 m or more.

With the conventional deposition apparatus or deposition method, when an EL layer was formed by deposition, almost the entire sublimated EL material adhered to the inner walls, shutter, or adhesion-preventing shield (a protective sheet for preventing the deposition material from adhering to the inner walls of the film forming chamber) of the film forming chamber of the deposition apparatus. For this reason, the utilization efficiency of expensive EL materials in the formation of the EL layer was extremely low, about 1% or less, and the production cost of light-emitting devices was extremely high.

Further, in the conventional deposition apparatuses, the spacing between the substrate and the deposition source was set to 1 m or more in order to obtain a uniform film. Further, a problem associated with substrates with a large surface area is that the film thickness can easily become nonuniform in the central zone and peripheral edges of the substrate. Moreover, because the deposition apparatus has a structure with a rotating substrate, a limitation is placed on the deposition apparatuses designed for substrates with a large surface area.

In addition, if a substrate with a large surface area and a mask for deposition are rotated together after being brought into intimate contact with each other, there is a risk of the displacement occurring between the mask and the substrate. Further, if the substrate or mask is heated during deposition, then dimensions change due to thermal expansion. As a result, the dimensional accuracy and positional accuracy decrease owing to the difference in thermal expansion coefficient between the mask and substrate.

With the foregoing in view, the applicant of the present application has suggested a deposition apparatus (Patent Document 1, Patent Document 2) as means for resolving the aforementioned problems.

### [Patent Document 1]

### JP-A-2001-247959.

### [Patent Document 2]

### JP-A-2002-60926.

### PROBLEMS ADDRESSED BY THE INVENTION

The present invention provides a production apparatus equipped with a deposition apparatus, which is a production apparatus reducing production cost by increasing the utilization efficiency of EL materials and having excellent uniformity and throughput of EL layer deposition.

Further, the present invention also provides a production apparatus for efficient deposition of EL materials on substrates with a large surface area such as 320 mm×400 mm, 370 mm×470 mm, 550 mm×650 mm, 600 mm×720 mm, 680 mm×880 mm, 1000 mm×1200 mm, 1100 mm×1250 mm, and 1150 mm×1300 mm. Further, the present invention also provides a deposition apparatus for obtaining a uniform film thickness over the entire substrate surface even on a substrate with a large surface area.

In addition, a large mask with a high mask accuracy is provided for conducting selective deposition on a substrate with a large surface area.

### MEANS TO RESOLVE THE PROBLEMS

In accordance with the present inventions in order to resolve the above-mentioned problems, a mask is fixed to the thermal expansion center in a frame. The fixing is conducted locally only to the thermal expansion center with an adhesive that has high resistance to temperature variations. The thermal expansion center is determined by the material, shape, outer periphery, and inner periphery of the frame.

Further, the mask body is formed from a material having the same thermal linear expansion coefficient as the substrate. Because, the mask body is also caused to expand thermally following the expanded state of the substrate, a deposition position accuracy can be maintained. Because the position in which the mask is fixed is the thermal expansion center, the alignment position is not changed even when the frame thermally expands under heating in a certain temperature range and the outer periphery and inner periphery thereof change.

Further, in accordance with the present invention, the substrate and mask are fixed, without rotation, during deposition. A film is formed on the substrate by moving the deposition source holder in the X direction, Y direction, or Z direction during deposition.

The constitution of the invention disclosed in the present specification is

a thin-sheet mask having a pattern opening, characterized in that

the mask is fixed to a frame in a stretched state and the mask is adhesively bonded in a location coinciding with a line passing through a thermal expansion center in the members of the frame.

Another constitution of the invention is

a thin-sheet mask having a pattern opening, characterized in that

the mask is fixed to a frame in a stretched state and the mask is adhesively bonded in a location on the outside of a line passing through a thermal expansion center in the members of the frame, and

the frame is caused to expand by heating during deposition and the mask maintains the stretched state.

If fixing is conducted on the outside of the thermal expansion center in the frame, the mask body is stretched as the frame expands under heating and the deflection can be prevented. Thus, tension of the mask can be maintained by using thermal expansion of the frame. Deposition is preferably carried out by conducting heating appropriate for the material that will be deposited, and the fixing position may be suitably determined so that the appropriate tension is applied to the mask at this heating temperature.

Further, in each of the above-described constitutions, four corners of the frame may have a curvature. Further in each of the above-described constitutions, the mask is characterized in that it is adhesively bonded to the frame with an adhesive having heat resistance. The mask may be also fixed to the frame by welding.

Yet another constitution of the present invention is

a container for accommodating a deposition material, which is disposed in a deposition source of a deposition apparatus, characterized in that

the cross section in a plane of the container has a rectangular or square shape and the opening portion through which the deposition material passes has a thin elongated shape.

A configuration may be also used in which the mounting angle of the deposition source can be freely set to match the evaporation center with a point on the substrate into which deposition is to be made when co-deposition is conducted. However, a certain spacing between the two deposition sources is required to tilt each deposition source at the angle. Therefore, it is preferred that the container has a prismatic columnar shape, as shown in FIG. 10, and the evaporation center be adjusted in the direction of the opening of the container. The container is composed of an upper part and a lower part. A plurality of upper parts with different angles at which the deposition material flies out from the opening may be prepared and an appropriate upper part may be selected. Because the spread of deposition differs depending on the deposition material, two deposition sources having different upper parts mounted thereon may be prepared when co-deposition is conducted.

Yet another constitution of the present invention is

a production apparatus comprising a loading chamber, a transportation chamber linked to the loading chamber, a plurality of film forming chambers linked to the transportation chamber, and a disposition chamber linked to the film forming chambers, characterized in that

the plurality of film forming chambers comprise means for fixing a substrate which is linked to an evacuation chamber for evacuating the inside of the film forming chambers, a mask, a frame for fixing the mask, alignment means for aligning the mask and the substrate, one or two deposition sources, means for moving the deposition sources inside the film forming chambers, and means for heating the substrate, and

the end portion of the mask is adhesively bonded in a location matching a line passing through a thermal expansion center in the members of the frame.

Yet another constitution of the present invention is a production apparatus comprising a loading chamber, a transportation chamber linked to the loading chamber, a plurality of film forming chambers linked to the transportation chamber, and a disposition chamber linked to the film forming chambers, characterized in that

the plurality of film forming chambers comprise means for fixing a substrate which is linked to an evacuation chamber for evacuating the inside of the film forming chambers, a mask, a frame for fixing the mask, alignment means for aligning the mask and the substrates, one or two deposition sources, means for moving the deposition sources inside the film forming chambers, and means for heating the substrate, and

the cross section in a plane of the container for accommodating a deposition material, which is disposed in the deposition source, has a rectangular or square shape and the opening portion has a thin elongated shape.

The above-described constitution is characterized in that, the container is composed of an upper part and a lower part, and evaporation of the material from the deposition source is adjusted by the shape of the opening portion in the upper part of the container. Furthermore, a middle lid having a plurality of orifices opened inside thereof may be provided in addition to the upper part and lower part in the container.

Further, each of the above-described configurations is characterized in that the aforementioned film forming chamber and disposition chamber comprise means capable of introducing a material gas or cleaning gas and linked to the chamber for evacuating the inside of the chambers.

Further, each of the above-described configurations is characterized in that the deposition source can be moved in the X direction, Y direction, or Z direction inside the film forming chamber.

Furthermore, each of the above-described configurations is characterized in that a shutter for partitioning the inside of the film forming chamber and shielding the deposition on the substrate is provided in the film forming chamber.

### BRIEF DESCRIPTION OF THE DRAWINGS

FIGS. 1A-1C are a perspective views and a cross-sectional views (Embodiment 1) illustrating the mask in accordance with the present invention.

FIGS. 2A-2C illustrates Embodiment 2.

FIGS. 3A-3B illustrates Embodiment 3.

FIG. 4 is a perspective view illustrating the mask in accordance with the present invention (Embodiment 1).

FIG. 5 illustrates a multichamber production apparatus (Example 1).

FIG. 6 is a top view of the deposition apparatus (Example 2).

FIGS. 7A-7B illustrates the disposition chamber and transportation mode (Example 2).

FIG. 8 is a top view of the inside of the film forming chamber (Working Example 3).

FIG. 9 is a top view of the inside of the film forming chamber (Example 3).

FIGS. 10A-10E illustrates the container in accordance with the present invention (Embodiment 4).

FIG. 11 illustrates the deposition apparatus in accordance with the present invention (Embodiment 4).

FIGS. 12A-12B illustrates the configuration of an active matrix EL display device.

FIGS. 13A-13G illustrates an example of an electronic device.

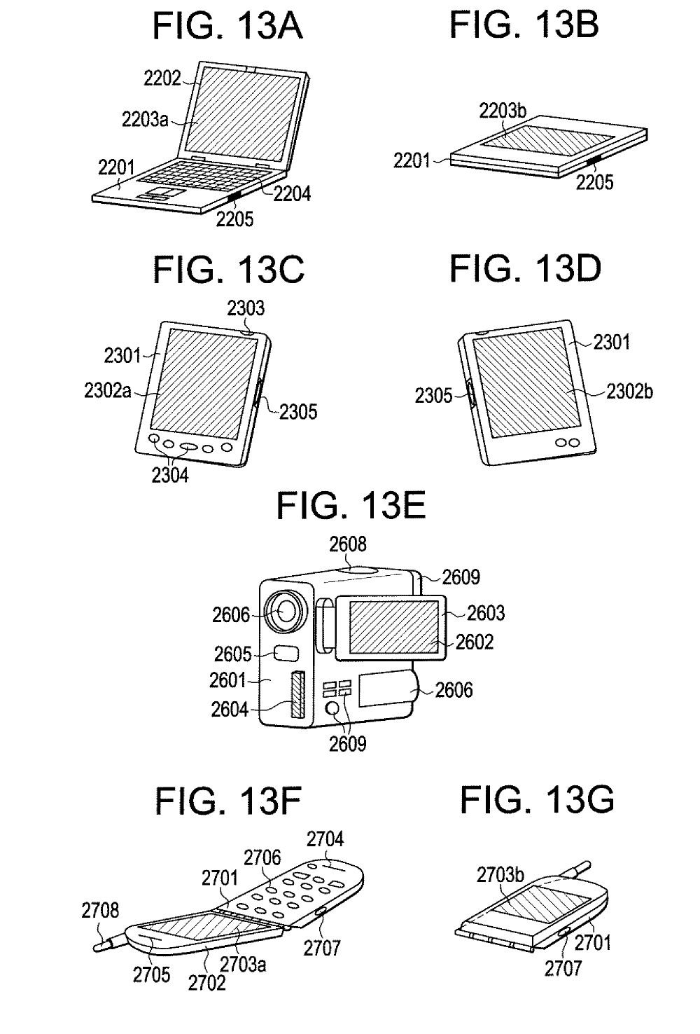

FIG. 14 is a block diagram of an electronic device shown in Example 6.

FIG. 15 is a block diagram of a controller.

FIG. 16 illustrates the charging mode of an electronic device shown in Example 6.

### PREFERRED EMBODIMENTS OF THE INVENTION

The preferred embodiments of the invention will be described below.

### Embodiment 1

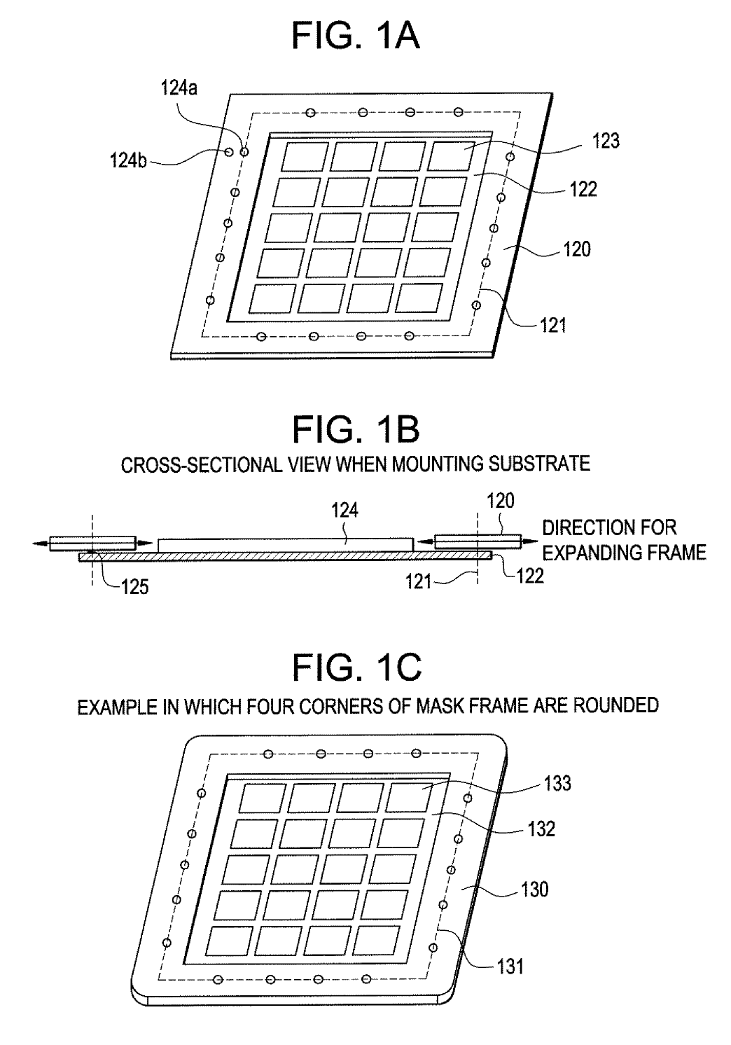

FIG. 1(A) is a perspective view of the mask in accordance with the present invention. A mask body 122 is fixed in a fixing position A124a disposed on a line passing through a thermal expansion center 121 in the width of a mask frame 120. Further, it is preferred that an arm (not shown in the figure) for supporting the mask frame be also supported in the fixing position A124a inside the deposition chamber.

Further, FIG. 1(B) is a cross-sectional view illustrating how a substrate 124 is carried during deposition. During deposition, the substrate 124, mask body 122, and mask frame 120 are aligned to a fixed position, and the mask body is brought into intimate contact over the entire surface with the deposition surface of the substrate by a magnetic force created by a magnet (not shown in the figure) provided at the rear surface of the substrate. In the example shown herein, fixing was conducted with the magnet, but mechanical fixing also may be employed. Further, an opening portion 123 is provided in the mask body, the deposition material that passed through the opening portion 123 forms a film, and a pattern is formed on the substrate 124.

Further, in accordance with the present invention, the substrate 124 and mask body 122 are fixed and deposition is conducted by moving the deposition source in the X direction or Y direction. A method involving moving the deposition source in the X direction or Y direction is suitable for deposition on large substrates.

In accordance with the present invention, a mask body using a material having a thermal expansion coefficient identical to that of the substrate is preferably used. For example, when a glass substrate is used, a 42 Alloy (Fe—Ni alloy: Ni 42%) or 36 Invar (Fe—Ni alloy: Ni 36%), which have a thermal expansion coefficient close to that of the glass, may be used for the mask body. Though the mask body and substrate are heated during deposition, because they expand to the same degree, hardly any displacement occurs. Further, the mask frame 120 is also heated, but because the position of the thermal expansion center does no change, hardly any displacement occurs, even if the mask frame 120 and mask body 122 are from different material and have different thermal expansion coefficients. The present invention is especially effective for deposition on large substrates in which displacement is easily caused by heating.

Further, the mask may be formed by an etching method or electroforming method. Further, the mask may be also formed by combining an etching method based on dry etching or wet etching with an electroforming method carried out in an electroforming tank of the same metal as that of the deposition mask.

Further, because the tension of the mask body 122 is maintained in a heated state, if fixing is conducted in a fixing position B124b located to the outer periphery from the thermal expansion center, instead of the fixing position A124a, then the tension of the mask body 122 can be maintained by using the expansion amount of the mask frame. The distance from the thermal expansion center to the fixing position B124b may be suitably determined according to the heating temperature during deposition, thermal expansion coefficient of the frame, and outer periphery and inner periphery of the frame.

Further, FIG. 1(C) illustrates an example in which four corners of the mask frame were rounded. Rounding the four corners of the mask prevents the corners of the mask frame is prevented from being damaged by any impacts. In FIG. 1(C), the reference numeral 130 stands for a mask frame, 131—a thermal expansion center, 132—a mask body, and 133—an opening portion.

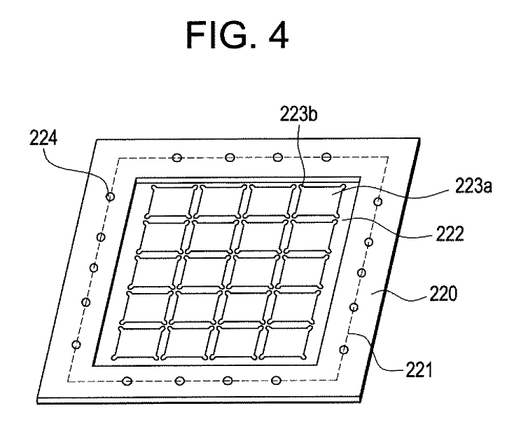

Further, FIG. 4 shows an example in which a clearance is formed and a play portion 223b is provided in the four corners of the opening portion 223a. Providing the play portion 223b prevents cracks from entering the mask body 232 from the corner of the adjacent opening portion even when a tension is applied to the mask body 232 and it is thermally expanded. Further, in FIG. 4, the reference numeral 230 stands for a mask frame, 231—a thermal expansion center, 232—a mask body, and 224—a fixing position.

### Embodiment 2

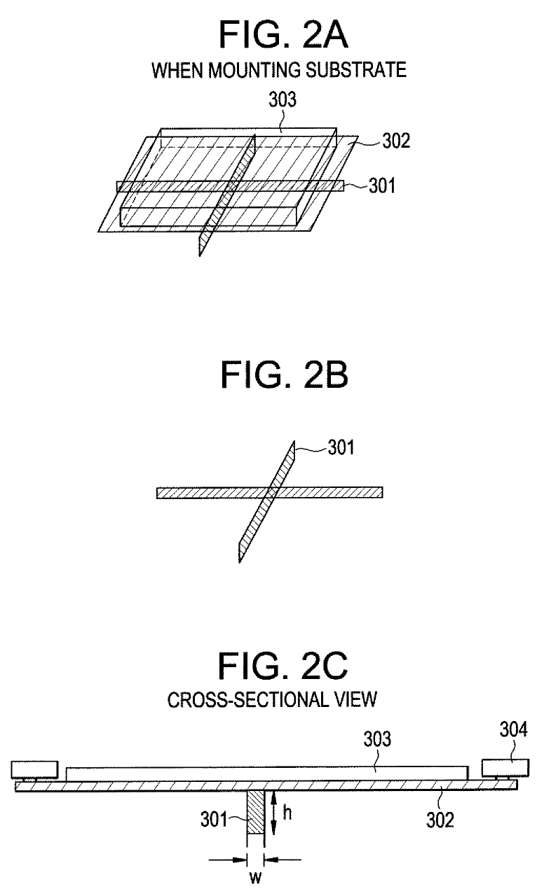

Here, the configuration of substrate holding means will be described in greater detail with reference to FIG. 2. When a substrate with a large surface area is used and gang printing is carried out (a plurality of panels are formed from one substrate), substrate holding means is provided to support the substrate so as to be in contact with the portions that will be scribe lines. Thus, a substrate is placed on substrate holding means and a deposition material is sublimated from the deposition source holder provided below the substrate holding means and deposited on the areas that are not in contact with the substrate holding means. As a result, the deflection of substrates with a large surface area can be suppressed to 1 mm or less.

FIG. 2(A) is a perspective view showing a substrate holding means 301 having a substrate 303 and a mask 302 placed thereon. FIG. 2(B) shows only the substrate holding means 301.

Further, FIG. 2(C) shows a cross-sectional view of the substrate holding means in which the substrate 303 was placed on the mask 302; the substrate holding means is composed of a metal sheet (typically, Ti or a shape memory alloy) with a height, h, of 10 mm-50 mm and a width 1 mm -5 mm. Further, the substrate holding means may be also a wire composed of a shape memory alloy. The substrate holding means is fixed to the mask 302 by welding or adhesively. Further, the mask 302 is fixed with an adhesive material in a position serving as a thermal expansion center of the mask frame 304.

The substrate holding means 301 inhibits the deflection of the substrate or the deflection of the mask under the weight of the substrate. Further, the substrate holding means 301 can inhibit the deflection of the mask and maintain the tension of the mask.

The shape of the substrate holding means 301 is not limited to that shown in FIG. 2(A)-FIG. 2(C) and is a shape which does not overlap the opening portion of the mask which is provided in the mask.

The present embodiment can be freely combined with Embodiment 1.

### Embodiment 3

Here, an example of conducting the deposition of a RGB pattern is shown.

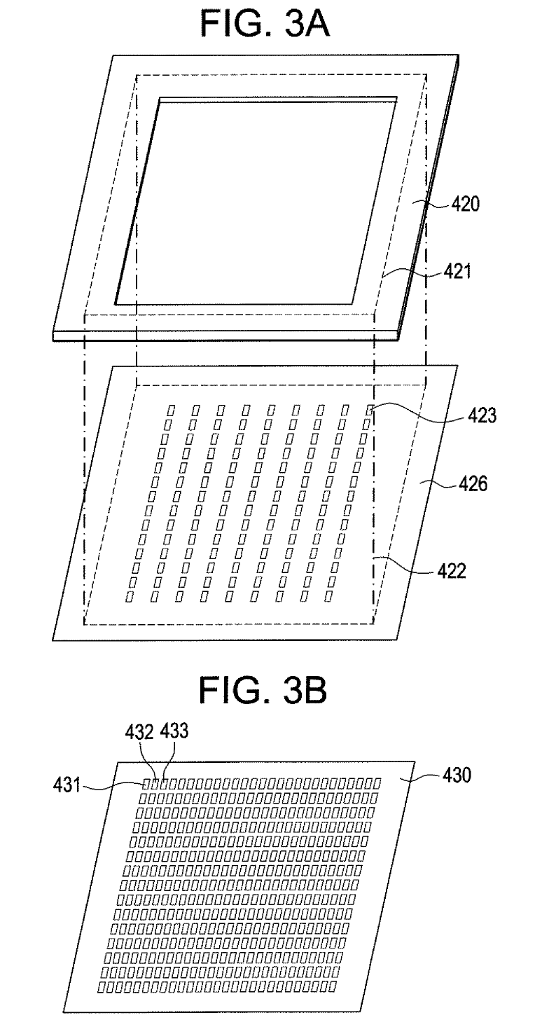

FIG. 3(A) is an exploded perspective view of a mask composed of a mask frame 420 and a mask body 422.

A thermal expansion center 421 of the mask frame 420 coincides with the adhesive bonding location 426 with the mask body 422. Further, the mask body is provided with an opening portion 423. The opening portion 423 is provided as a pattern of one kind among the RGB. Here, for the sake of simplicity, a mask having an opening portion with 9 rows×15 columns is shown, but it goes without saying that this shape is not limiting, and the mask may correspond to the desired number of pixels, for example, to 640×480 pixels of a VGA class or 1024×768 pixels of a XGA class.

Three masks are prepared for RGB patterning. When three masks are prepared, a common mask design is employed for the mask bodies, but when the masks are fixed to the mask frame, each mask is individually adhesively bonded to obtain the prescribed pixel position. Alternatively, the deposition may be conducted by employing one mask and shifting the mask with respect to the substrate for each ROB during alignment. Further, the deposition may be also conducted by employing one mask and shifting the mask with respect to the substrate for each RGB during alignment inside one chamber.

FIG. 3(B) is a perspective view of the substrate after the deposition of three kinds of RGB was conducted. A deposited film 431 for red color, a deposited film 432 for green color, and a deposited film 433 for blue color have been regularly deposited on the substrate 430. A pattern comprising a total of 405 (27 rows×15 columns) units has been formed.

This embodiment can be freely combined with Embodiment 1 or Embodiment 2.

### Embodiment 4

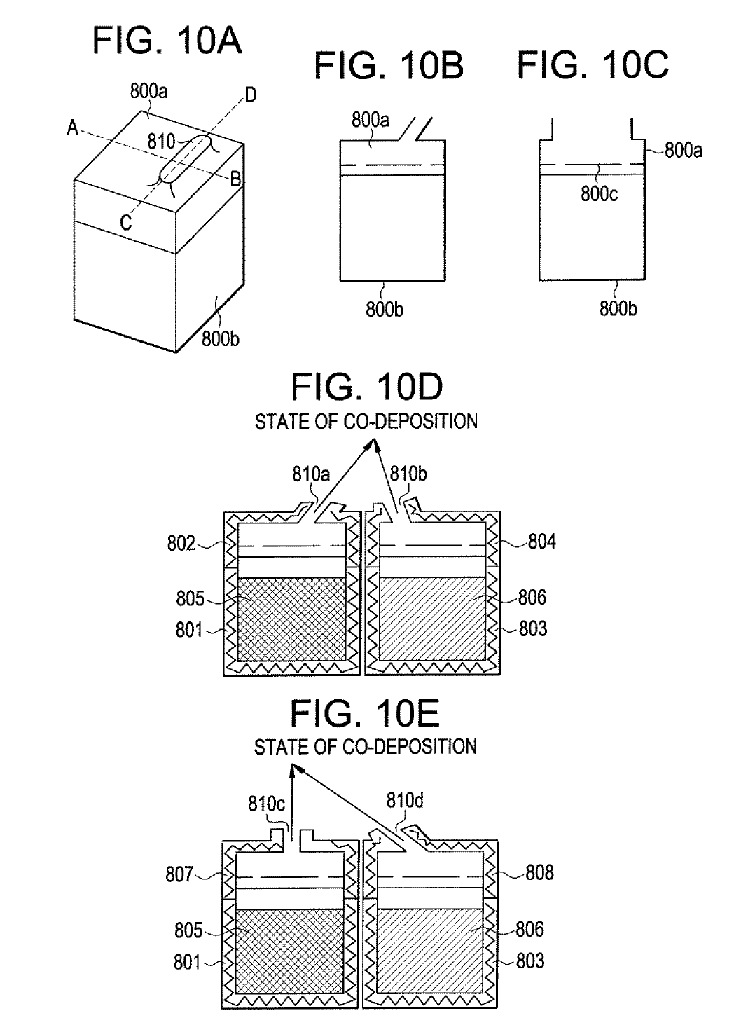

Here, a container for accommodating a deposition material is shown in FIG. 10. FIG. 10(A) is a perspective view of the container. FIG. 10(B) is a cross-sectional view obtained by cutting along the chain line A-B. FIG. 10(C) is a cross-sectional view obtained by cutting along the dot line C-D.

When the mounting angle of the deposition source is changed, a cylindrical crucible and a heater surrounding the crucible are also inclined. Therefore, when co-deposition is carried out by using two crucibles, the spacing therebetween is increased. If the spacing is increased, two different deposition materials are difficult to mix homogeneously. Furthermore, when it is desirable to conduct deposition with a small gap between the deposition source and the substrate, then a uniform film is difficult to obtain.

In accordance with the present invention, the evaporation center is adjusted with an opening 810 in the container upper part 800a, rather than by changing the mounting angle of the deposition source. The container is composed of the container upper part 800a, a container lower part 800b, and a middle lid 800c. A plurality of small orifices are provided in the middle lid 800c, and the deposition material passes through those orifices during deposition. Further, the container is formed of a material such as a BN sintered body, a BN and AlN composite sintered body, quartz glass, and graphite and can withstand high temperature, high pressure, and low pressure. The deposition direction and spread differ depending on the deposition material. Therefore, the container is appropriately prepared in which the surface area of the opening 810, the guide portion of the opening, and the position of the opening are adjusted according to each deposition material.

With the container in accordance with the present invention, the deposition center can be adjusted without tilting the heater of the deposition source. Further, as shown in FIG. 10(D), in co-deposition, the orientations of the opening 810a and 810b can be aligned, spacing between a plurality of containers accommodating a plurality of different deposition materials (materials A805, material B806) can be decreased, and deposition can be conducted, while homogeneously mixing the materials. Referring to FIG. 10(D), heating means 801-804 are connected to individual power sources and mutually independent temperature control thereof is conducted. Furthermore, a uniform film can be obtained even when it is desirable to conduct deposition with a spacing between the deposition source and substrate decreased, for example, to 20 cm or less.

Further, an example different from that shown in FIG. 10(D) is shown in FIG. 10(E). In the example shown in FIG. 10(E), deposition is conducted by using an upper part with an opening 810c provided for evaporation in the vertical direction and by using an upper part having an opening 810d inclined according to this direction. In the configuration shown in FIG. 10(E), too, heating means 801, 803, 807, and 808 are connected to separate power sources and mutually independent temperature control thereof is conducted.

The container in accordance with the present invention shown in FIG. 10 has a fine long opening. Therefore, the uniform deposition region is expanded and the container is suitable for uniform deposition on a fixed substrate with a large surface area.

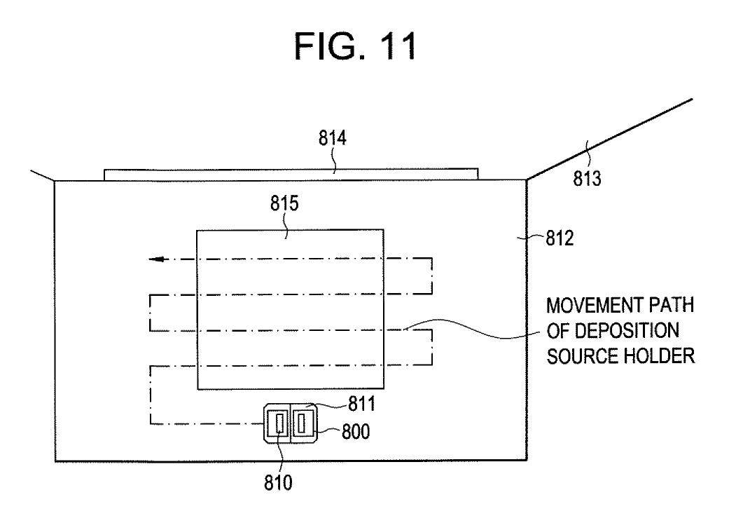

FIG. 11 is a top view of a film forming apparatus for conducting deposition by using the container shown in FIG. 10 with a fixed substrate with a large surface area.

A substrate 815 is transported from a transportation chamber 813 into a film forming chamber 812 through a shutter 814. If necessary, alignment of the substrate and a mask (not shown in the figure) is conducted in the transportation chamber 813 or film forming chamber 812.

The container 800 composed of the container upper portion 800a having the opening 810 and the container lower portion 800b is disposed in the deposition source holder 811. The deposition source holder 811 is moved below the substrate 815 with movement means (not shown in the figure) that can move in the X direction, Y direction, or Z direction. A chain line in FIG. 11 shows an example of the movement path of the deposition source holder.

In the deposition apparatus shown in FIG. 11, the clearance distance, d, between the substrate 813 and the deposition source holder 811 is typically decreased to 30 cm or less, preferably 20 cm or less, even more preferably 5 cm-15 cm, and the utilization efficiency of the deposition material is greatly increased.

Further, there is a risk of the deposition mask (not shown in the figure) being heated due to the decrease in the clearance distance, d, between the substrate 813 and the deposition source holder 811 typically to 30 cm or less, preferably to 5 cm-15 cm. Therefore, it is preferred that a metal material (for example, a material such as a metal with a high melting point such as tungsten, tantalum, chromium, nickel, or molybdenum or alloys containing such elements, stainless steel, Inconel, and Hastelloy) that has a low thermal expansion coefficient and high resistance to heat-induced deformation be used for the deposition mask 14. An example of such a material is an alloy with low thermal expansion which contains nickel 42% and iron 58%. Further, a structure in which a cooling medium (cooling water, cooling gas) is circulated to the deposition mask for cooling the heated deposition mask may be also provided.

This embodiment can be freely combined with any of Embodiments 1 to 3.

The present invention of the above-described constitution will be explained in greater detail with the examples described hereinbelow.

### EXAMPLES

### Example 1

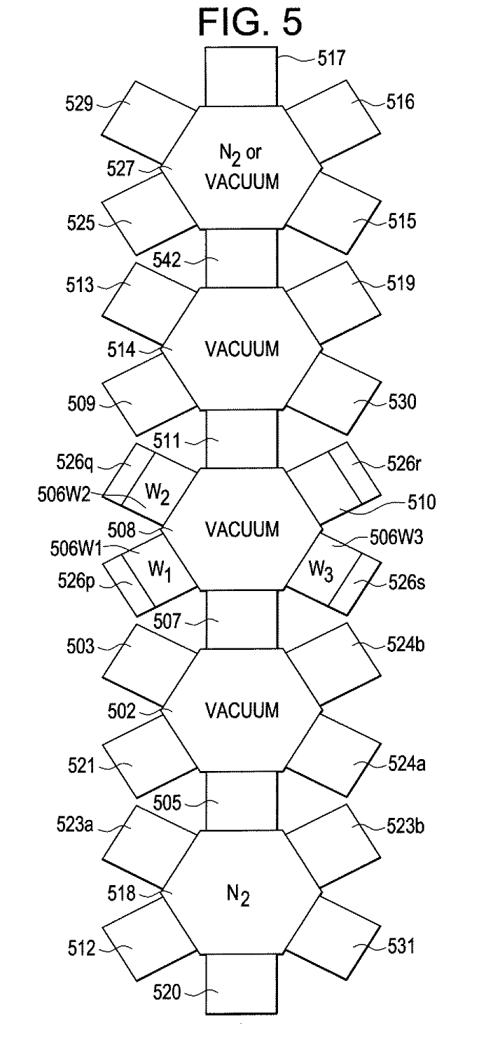

FIG. 5 is a top view of the production apparatus of a multichamber type. In the production apparatus shown in FIG. 5, the chambers are disposed in the order of tasks performed.

In the production apparatus shown in FIG. 5, at least the transportation chambers 504a, 504b, 508, 514 are constantly maintained under vacuum and the film forming chambers 506W1, 506W2, 506W3 are constantly maintained under vacuum. Therefore, the operations of evacuating the film forming chambers and the operations of filling the film forming chambers with nitrogen can be omitted and a film forming treatment can be carried out continuously within a short time.

Deposited in one film forming chamber is only one layer of the EL layer (comprises a hole transfer layer, a hole injection layer, a light-emitting layer, an electron transfer layer, an electron injection layer, and the like) composed of a stack of layers composed of different materials. A deposition source holder capable of moving inside a film forming chamber is provided in each film forming chamber. A plurality of such deposition source holders are prepared and a plurality of containers (crucibles) having EL materials introduced therein are appropriately provided and disposed in the film forming chambers. The substrate can be set in a face-down system, the position alignment of the deposition mask can be carried out with a CCD or the like, and film formation can be selectively carried out by conducting the deposition by a resistance heating method.

The disposition of the containers (crucibles) having EL materials introduced therein, replacement of components of the deposition holder, and the like, are conducted in the disposition chambers 526p, 526q, 526r, 526s. The EL materials are accommodated in advance in the containers (typically, crucibles) by material makers. The disposition is preferably conducted without contact with the atmosphere, and when transported from material makers, the crucibles are introduced into the disposition chambers in a state in which they are air-tightly sealed in a second container. The disposition chambers are evacuated, the crucibles are removed from the second containers in the disposition chambers, and the crucibles are disposed in the deposition holders. In this case, the crucibles and EL materials accommodated in the crucibles can be prevented from contamination.

In accordance with the present invention, because a white light-emitting element with a three-layer structure of a layer comprising an organic compound was realized, the formation of the layer comprising the organic compound may be conducted with a three-chamber configuration at a minimum. Employing three chambers can shorten the process time and also can reduce the cost of production apparatus. Furthermore, the thickness of each film may be as small as 20 nm-40 nm which is also advantageous from the standpoint of material cost.

For example, when a white light-emitting element is formed, a hole transfer layer (HTL) serving as a first light-emitting layer may be deposited in a film forming chamber 506W1, a second light-emitting layer may be deposited in a film depositing chamber 506W2, an electrode transfer layer (ETL) may be deposited in the film forming chamber 506W3, and then a cathode may be formed in a film forming chamber 510. A blue fluorescent material having hole transfer capability, such as TPD and α-NPD, may be used as the light-emitting material in the first light-emitting layer. An organometallic complex comprising platinum as a central metal is effective as a light-emitting material in the second light-emitting layer. More specifically, if a substance represented by the following structural formulas (1)-(4) is admixed to a host material at a high concentration (10 wt. %-40 wt. %, preferably 12.5 wt.-20 wt. %), then both the phosphorescent emission and excimer emission thereof can be led out. The present invention is, however, not limited to those materials and any material may be used, provided that it is a phosphorescent material generating phosphorescent emission and excimer emission at the same time.

### [Formula 1]

### [Formula 2]

### [Formula 3]

### [Formula 4]

Furthermore, examples of electron transfer materials that can be used for the electron transfer layer (ETL) include metal complexes such as tris(8-quinolinolato)aluminum (abbreviation: Alq₃), tris(4-methyl-8-quinolinolato)aluminum (abbreviation: Almq₃), bis(10-hydroxybenzo[h]-quinolinolato)beryllium (abbreviation: BeBq₂), bis(2-methyl-8-quinolinolato)-(4-hydroxy-biphenylyl)-aluminum (abbreviation: BAlq), bis[2-(2-hydroxyphenyl)-benzoxalato]zinc (abbreviation: Zn(BOX)₂), bis[2-(2-hydroxyphenyl)-benzothiazolato]zinc (abbreviation: Zn(BTZ)₂). Examples of suitable compounds other than metal complexes include oxadiazole derivatives such as 2-(4-biphenylyl)-5-(4-tert-butylphenyl)-1,3,4-oxadiazole (abbreviation; PBD), and 1,3-bis[5-(p-tert-butylphenyl)-1,3,4-oxadiazole-2-yl]benzene (abbreviation: OXD-7), triazole derivatives such as 3-(4-tert-butylphenyl)-4-phenyl-5-(4-biphenylyl)-1,2,4-triazole (abbreviation: TAZ) and 3-(4-tert-butylphenyl)-4-(4-ethylphenyl)-5-(4-biphenylyl)-1,2,4-triazole (abbreviation: p-EtTAZ), imidazole derivatives such as 2,2′,2″-(1,3,5-benzenetriyl)tris[1-phenyl-1H-benzimidazole] (abbreviation: TPBI), and phenanthroline derivatives such as bathophenanthroline (abbreviation: BPhen) and bathocuproine (abbreviation: BCP).

In particular, in the second light-emitting layer, a metal complex of one kind may be admixed at a high concentration (10 wt. %-40 wt. %, preferably 12.5 wt. %-20 wt. %) by co-deposition. Therefore, concentration control is facilitated and the process is suitable for mass production.

Further, a simple mask for deposition in the region outside the location where a lead-out electrode is exposed (location where a FPC will be thereafter pasted) may be used as the deposition mask.

In order to obtain a double-side light-emitting panel, the cathode can be a laminate of a thin metal film and a transparent conductive film. The thin metal film (Ag or MgAg) may be with a thickness of 1 nm-10 nm by a resistance heating method, and a transparent conductive film is formed by sputtering. Therefore, the cathode can be formed within a short time.

Here an example of fabricating a white light-emitting panel was described, but panels with monochromatic light emission (green light, red light, blue light, and the like) can be also fabricated.

Described hereinbelow is a procedure in which a substrate that was provided in advance with an anode (first electrode) and an insulator (partition wall) for covering the end portions of the anode is transported into the production apparatus shown in FIG. 5 and a light emitting device is fabricated. When a light-emitting device of an active matrix type is fabricated, a plurality of thin-film transistors connected to the anode (TFT for current control) and other thin film transistors (TFT for switching and the like) are provided in advance on the substrate and a drive circuit composed of a thin-film transistor is also provided. Further, fabrication with the production apparatus shown in FIG. 5 can be also conducted when a light-emitting device of a simple matrix type is fabricated.

The aforementioned substrate (600 mm×720 mm) is set into a substrate placing chamber 520. The substrate size is 320 mm×400 mm, 370 mm×470 mm, 550 mm×650 mm, 600 mm×720 mm, 680 mm×880 mm, 1000 mm×1200 mm, 1100 mm×1250 mm. Even a substrate with a surface area as large as 1150×1300 can be processed.

The substrate (the substrate provided with an anode and an insulator covering the end portions of the anode) set into the substrate placing chamber 520 is transported into a transportation chamber 518 maintained under atmospheric pressure. A transportation mechanism (transportation robot or the like) for transporting and turning over the substrate is provided in the transportation chamber 518.

Further, respective transportation mechanisms and evacuation means are provided in the transportation chambers 508, 514, 502. The robot provided in the transportation chamber 518 can turn the substrate over and can turn it over and transport into a receiving chamber 505. The receiving chamber 505 is linked to an evacuation chamber and can be evacuated to vacuum. Upon evacuation, an inactive gas can be introduced to obtain the atmospheric pressure.

A turbomolecular pump of a magnetic levitation type, a cryopump, or a dry pump is provided as the aforementioned evacuation chamber. As a result, the attained degree of vacuum in the transportation chambers linked to various chambers can be reduced to 10⁻⁵-10⁻⁶ Pa. Further, a reverse diffusion of impurities from the pump or evacuation system can be controlled. An inactive gas such as nitrogen or rare gas is used as the gas introduced into the apparatus in order to prevent impurities from penetrating into the apparatus. Those gases that are introduced into the apparatus are purified to a high degree of purity with a gas purifier prior to introduction into the apparatus. Therefore, a gas purifier has to be provided so that the gases are introduced into the deposition apparatus after purification. In this case, oxygen or water and other impurities contained in the gases can be removed in advance. Therefore, those impurities can be prevented from being introduced into the apparatus.

Further, prior to setting into the substrate placing chamber 520, surface dust is preferably removed by washing the surface of the first electrode (anode) with a porous sponge (typically made from PVA (polyvinyl alcohol), Nylon, and the like) impregnated with a surfactant (with weak alkaline properties) in order to reduce point defects. A washing apparatus comprising a roll brush (manufactured from PVA) which rotates around an axial line parallel to the substrate surface and is in contact with the substrate surface may be used or a washing apparatus comprising a disk brush (manufactured from PVA) which rotates around an axial line perpendicular to the substrate surface and is in contact with the substrate surface may be used as the cleaning mechanism.

The substrate is then transported from the transportation chamber 518 into the receiving chamber 505, and the substrate is then transported from the receiving chamber 505 into the transportation chamber 502, without contact with the atmosphere.

Further, in order to prevent shrinking, vacuum heating is preferably conducted immediately prior to depositing a film containing an organic compound. Thus, the substrate is transported from the transportation chamber 502 into a multistage vacuum heating chamber 521 and annealing for degassing is carried out under vacuum (5×10⁻³ Torr (0.665 Pa) or below, preferably, 10⁻⁴-10⁻⁶ Pa) in order to remove thoroughly moisture and other gases contained in the substrate. In the multistage vacuum heating chamber 521, a plurality of substrates are uniformly heated by using flat-plate heaters (typically, sheath heaters). A plurality of such flat-plate heaters are disposed and heating can be conducted from both sides, so that the substrates are sandwiched between the flat-plate heaters. It goes without saying that heating can be also conducted from one side. In particular, when an organic resin film is used as a material for an insulating film or partition wall, because some of organic resin materials easily adsorb moisture and there is a risk of degassing, an effective approach is to conduct heating at a temperature of 100° C.-250° C., preferably 150° C.-250° C., for example, for 30 min or longer and then conduct natural cooling for 30 min and vacuum heating to remove the adsorbed moisture prior to forming a layer containing the organic compound.

Further, UV irradiation may be employed, while conducting heating at a temperature of 200-250° C. in an inactive gas atmosphere, in addition to the aforementioned vacuum heating. Further, the treatment of irradiating with UV rays, while conducting heating at a temperature of 200-250° C. in an inactive gas atmosphere, may be also conducted without conducting vacuum heating.

Further, if necessary, a hole injection layer composed of a polymer material may be formed by an ink-jet method, spin coating method, or spray method under an atmospheric pressure or reduced pressure in the film forming chamber 512. After coating with the ink-jet method, a uniform film thickness may be obtained with a spin coater. Similarly, after coating with the spray method, a uniform film thickness may be obtained with a spin coater. A film may be also formed by the ink-jet method in vacuum with vertical parallel arrangement of substrates.

For example, a poly(ethylene dioxythiophene)/poly(styrenesulfonic acid) aqueous solution (PEDOT/PSS), polyaniline/camphorsulfonic acid aqueous solution (PANI/CSA), PTPDES, Et-PTPDEK, or PPBA used as a hole injection layer (anode buffer layer) may be coated and fired over the entire surface on the first electrode (anode) in the film forming chamber 512. The firing is preferably conducted in the multistage heating chambers 523a, 523b.

When the hole injection layer (HIL) composed of a polymer material is formed with a coating method using a spin coater or the like, the flatness is increased and coverage of the film formed thereon and the uniformity of film thickness can be improved. In particular, because the film thickness of the light-emitting layer is uniform, homogeneous light emission is obtained. In this case, after the hole injection layer has been formed by the coating method, heating under atmospheric pressure or vacuum heating (100-200°) is preferably conducted immediately prior to film formation by a deposition method.

For example, the formation of an EL layer may be carried out by the deposition method, without contact with air, by washing the surface of the first electrode (anode) with a sponge, transporting into the substrate placing chamber 520, transporting into the film forming chamber 512a, coating a poly(ethylene dioxythiophene)/poly(styrenesulfonic acid) aqueous solution (PEDOT/PSS), over the entire surface to a film thickness of 60 nm by a spin coating method, then transporting into multistage heating chambers 523a, 523b, pre-firing for 10 min at a temperature of 80° C., main firing for 1 h at a temperature of 200° C., then transporting into a multistage vacuum heating chamber 521, vacuum heating (170° C., heating 30 min, cooling 30 mm) immediately prior to deposition, and then transporting into film forming chambers 506W1, 506W2, and 506W3. In particular, when an ITO film is used as an anode material and peaks and valleys of fine particles are present on the surface, the effect thereof can be reduced by forming the PEDOT/PSS film to a thickness of 30 nm or more. Further, it is preferred that ultraviolet irradiation be carried out in the UV treatment chamber 531 in order to improve wettability of PEDOT/PSS.

Further, when a PEDOT/PSS film is formed by a spin coating method, the film is formed over the entire surface. Therefore, it is preferred that the end surfaces or peripheral edges of the substrate, terminal portions, and zones of contact with the cathode and lower wiring be selectively removed. The selective removal is preferably conducted by O₂ ashing by using a mask in a pretreatment chamber 503. The pretreatment chamber 503 comprises plasma generation means and dry etching is conducted therein by exciting one or a plurality of gases selected from Ar, H, F, and O and generating plasma. Using a mask makes it possible to remove selectively only the unnecessary portions.

Further, the deposition masks are stocked in mask stock chambers 524a, 524b and appropriately transported into the film forming chamber when deposition is conducted. If a large substrate is used, then the surface area of the mask increases. As a result, a frame for fixing the mask becomes larger and a large number of masks are difficult to stock. For this reason, here, two mask stock chambers 524a, 524b were prepared. Cleaning of deposition masks may be conducted in the mask stock chambers 524a, 524b. Further, during deposition, the mask stock chambers are empty. Therefore, substrates can be stocked therein after film formation or treatment.

The substrates are then transported from the transportation chamber 502 into the receiving chamber 507 and then the substrates are transported from the receiving chamber 507 into the transportation chamber 508, without contact with air.

The substrates are then appropriately transported into film forming chambers 506W1, 506W2, 506W3 linked to the transportation chamber 508 and organic compound layers composed of low-molecular materials and serving as the hole transfer layer, light-emitting layer, and electron transfer layer are appropriately formed. Appropriately selecting the EL material makes it possible to form a light-emitting element demonstrating monochromatic (more specifically, white) light emission as the entire light emitting element. Further substrate transportation between the transportation chambers is conducted via the receiving chambers 540, 541, 511, without contact with air.

Then, the substrates are transported into the film forming chamber 510 by the transportation mechanism disposed in the transportation chamber 514 and a cathode is formed. The cathode is preferably transparent or semitransparent. It is preferred that the cathode be formed from a thin (1 nm-10 nm) metal film (alloys such as MgAg, MgIn, CaF₂, LiF, and CaN, or films formed by co-deposition of an element of Group 1 or Group 2 of the periodic table of the elements and aluminum, or laminated films of those films) formed by a deposition method using resistance heating or a laminate of such thin metal film (1 nm-10 nm) and a transparent conductive film. After the substrates have been transported from the transportation chamber 508 into the transportation chamber 514 via the receiving chamber 511, they are transported into the film forming chamber 509 and a transparent conductive film is formed by using a sputtering method.

A light-emitting element of a laminated structure having a layer comprising an organic compound is formed by the above-described process.

It is also possible to conduct sealing by transporting into a film forming chamber 513 linked to the transportation chamber 514 and forming a protective film composed of a silicon nitride film or a silicon nitride oxide film. Here, a target composed of silicon, a target composed of silicon oxide, or a target composed of silicon nitride oxide is provided inside the film forming chamber 513.

Further, a protective film may be formed by moving a rod-like target with respect to the fixed substrate. Further, a protective film may be formed by moving the substrate with respect to a fixed rod-like target.

For example, a silicon nitride film can be formed on the cathode by using a disk-like target composed of silicon and employing a nitrogen atmosphere or an atmosphere comprising nitrogen and argon as the atmosphere of the film forming chamber. Further, a thin film comprising carbon as the main component (DLC film, CN film, amorphous carbon film) may be formed as the protective film, and a film forming chamber using a CVD method may be provided separately. A diamond-like carbon film (also called a DLC film) can be formed by a plasma CVD method (typically, a RF plasma CVD method, microwave CVD method, electron cyclotron resonance (ECR) CVD method, thermal filament CVD method, and the like), combustion flame method, sputtering method, ion beam deposition method, laser deposition method and the like. Hydrogen gas and a hydrocarbon gas (for example, CH₄, C₂H₂, C₆H₆, and the like) is used as the reaction gas employed for film formation and the film is formed by ionization with a glow discharge and acceleration bombardment with the ions of the cathode with a negative self-bias applied thereto. Further, a CN film may be formed by using C₂H₄ gas and N₂ gas as the reaction gas. The DLC film and CN film are insulting films transparent or semitransparent to visible light. Transparency to visible light indicates a transmittance of visible light of 80-100%, and semitransparency to visible light indicates a transmittance of visible light of 50-80%.

Further, a protective film composed of a laminate of a first inorganic insulating film, a stress relaxation film, and a second inorganic insulating film may be formed instead of the above-described protective film on the cathode. For example, it may be formed by forming a cathode, then transporting into the film forming chamber 513, forming a first inorganic insulating film to 5 nm-50 nm, transporting to the film forming chamber 506W1, 506W2, or 506W3, forming a stress relaxation film having moisture absorptivity and transparency by a deposition method (inorganic layer or a layer comprising an organic compound) to 10 nm-100 nm, then again transporting to the film forming chamber 513 and forming a second inorganic insulating film to 5 nm-50 nm.

The substrate having the light-emitting elements formed thereon is then transported to a sealing chamber 519.

A sealing substrate is set from the outside into the loading chamber 517 and prepared. The sealing substrate is transported from the loading chamber 517 into the transportation chamber 527 and into an optical film attaching chamber 529 for attaching an optical filter (color filter, polarizing film, and the like) and, if necessary, a drying agent. Further, a sealing substrate which has an optical film (color filter, polarizing plate) attached thereto in advance may be also set into the loading chamber 517.

Further, annealing is preferably carried out in advance in a multistage heating chamber 516 to remove impurities such as moisture present in the sealing substrate. Further, when a sealing material for pasting to the substrate provided with the light-emitting element is formed on the sealing substrate, the sealing material is formed in a dispenser chamber 515, the sealing substrate with the sealing material formed thereon is transported into the transportation chamber 514 via the receiving chamber 542 and then to the sealing substrate stock chamber 530. Here, an example was presented in which the sealing material was formed on the sealing substrate, but this example is not limiting and the sealing material may be formed on the substrate where the light-emitting element was formed. Further, deposition masks used during deposition may be also stocked in the sealing substrate stock chamber 530.

Further, because the present example relates to a double-side emission structure, the sealing substrate may be transported to the optical film attachment chamber 529 and an optical film may be attached to the inner side of the sealing substrate. Alternatively, the substrate provided with the light-emitting element may be bonded to the sealing substrate and then transported into the optical film attachment chamber 529, where an optical film (color filter or polarizing plate) may be attached to the outer side of the sealing substrate.

Then, the substrate and sealing substrate are bonded in the sealing chamber 519 and the sealing material is cured by irradiating the pair of bonded substrates with UV rays by using the UV irradiation mechanism provided in the sealing chamber 519. It is preferred that irradiation with UV rays be conducted from the side of the sealing substrate where TFTs, which shield the light, are not provided. Further, a UV-curable and heat-curable resin was used as a sealing material, but no limitation is placed thereon, provided that it is an adhesive material. For example, a resin curable only with UV rays may be used.

Further, the air-tight space may be filled with a resin rather than with an inactive gas. When UV irradiation is conducted from the side of the sealing substrate in case of bottom-side emission type, the light does not pass through the cathode. Therefore, no limitation is placed on the resin material for filling and a UV-curable resin or non-transparent resin may be used. However, when irradiation with UV rays is conducted from the side of the sealing substrate in case of double-side emission, the UV rays pass through the cathode and the EL layer is damaged. Accordingly, it is preferred that UV-curable resin be not used. Therefore, in case of double-side emission type, it is preferred that a thermosetting transparent resin be used as the resin for filling.

Then, the pair of bonded substrates are transported from the sealing chamber 519 to the transportation chamber 514 and then via the receiving chamber 542 from the transportation chamber 527 to a removal chamber 525 for removal.

Upon removal from the removal chamber 525, heating is conducted and the sealing material is cured. In case of upper surface emission and filling with a thermosetting resin, curing can be conducted simultaneously with heat treatment conducted to cure the sealing material.

As described hereinabove, with the production apparatus shown in FIG. 5, the light-emitting elements are not exposed to air till they are sealed in an air-tight space. Therefore, highly reliable light-emitting devices can be fabricated.

A control unit (not shown in the figures) is provided for realizing full automation by controlling a path of moving the substrates through individual treatment chambers.

### Example 2

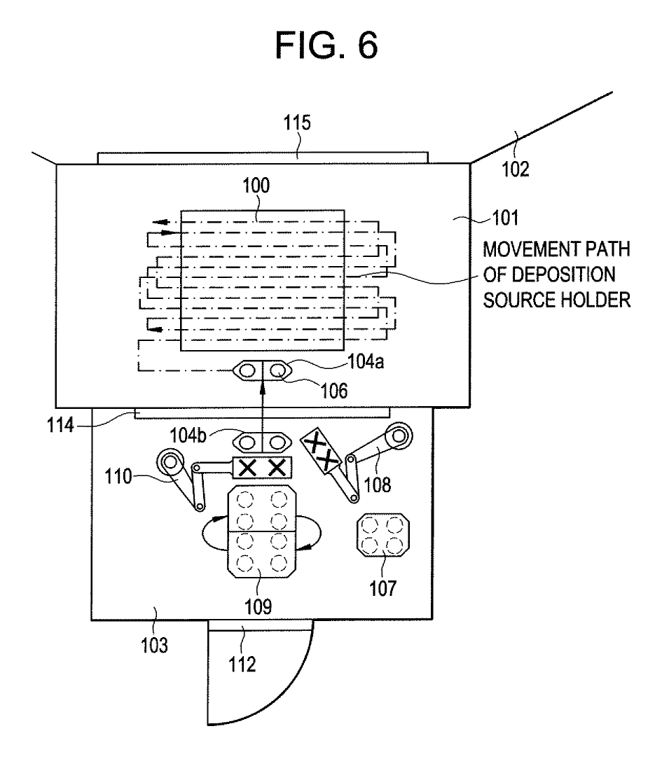

FIG. 6 is an example of the top view of a deposition apparatus.

Referring to FIG. 6, a film forming chamber 101 comprises a substrate holding means (not shown in the figures), a first deposition source holder 104a and a second deposition source holder 104b having deposition shutters (not shown in the figures) disposed therein, means (not shown in the figure) for moving those deposition source holders, and means (evacuation means) for creating the atmosphere under reduced pressure. The film forming chamber 101 is evacuated to a vacuum degree of 5×10⁻³ Torr (0.665 Pa) or less, preferably to 10⁻⁴-10⁻⁶ Pa with the means for creating the atmosphere under reduced pressure.

Further, a gas introduction system (not shown in the figures) for introducing a material gas at several sccm during deposition and inactive gas (Ar, N₂, and the like) introduction system (not shown in the figures) for creating normal pressure inside the film forming chamber are linked to the film forming chamber. Further, a cleaning gas (one or several gases selected from H₂, F₂, NF₃, or O₂) introduction system may be also provided. It is preferred that the material gas does not flow to the gas release opening at the shortest distance from the gas introduction opening.

A high-density film may be obtained by introducing the material gas intentionally during film formation and including the components of the material gas into the organic compound layer, and permeation and diffusion of impurities such as oxygen or moisture that cause deterioration into the film may be blocked. Specific examples of the material gas include one or a plurality of gases selected from silane gases (monosilane, disilane, trisilane, and the like), SiF₄, GeH₄, GeF₄, SnH₄, or hydrocarbon gases (CH₄, C₂H₂, C₂H₄, C₆H₆, and the like). Further, a gas mixture obtained by diluting those gases with hydrogen, argon, or the like, is also included. Those gases that are introduced into the apparatus are purified to a high degree of purity with a gas purifier prior to introduction into the apparatus. Therefore, a gas purifier has to be provided so that the gases are introduced into the deposition apparatus after purification. In this case, residual gases (oxygen, water and other impurities) contained in the gases can be removed in advance. Therefore, those impurities can be prevented from being introduced into the apparatus.

For example, when defective portions such as pinholes and short circuits occur after Si was included in the film by introducing monosilane gas during deposition and the light-emitting elements were produced, a self-healing effect can be obtained in which the Si participates in a reaction due to heat generation in those defective portions and forms an insulator with insulating properties such as SiOx and SiCx, leakage in the pinholes and short circuit portions is reduced, and the development of point defects (dark spots and the like) is prevented.

Further, when the aforementioned material gas is introduced, a turbomolecular pump or dry pump is preferably provided in addition to a cryopump.

Further, in the film forming chamber 101, the deposition source holder 104 can move many times along the movement path shown by a chain line in FIG. 6. The movement path shown in FIG. 6 is merely an example and is not limiting. In order to obtain a uniform film thickness, it is preferred that the deposition source holder be moved by shifting the movement path as shown in FIG. 6 and deposition be conducted. Further, reciprocal movement along the same movement path is also possible. The film thickness uniformity may be improved and time required to deposit a film may be shortened by appropriately changing the movement rate of the deposition holder for each segment of the movement path. For example, the deposition source holder may be moved in the X direction or Y direction at a rate of 30 cm/mm to 300 cm/mm.

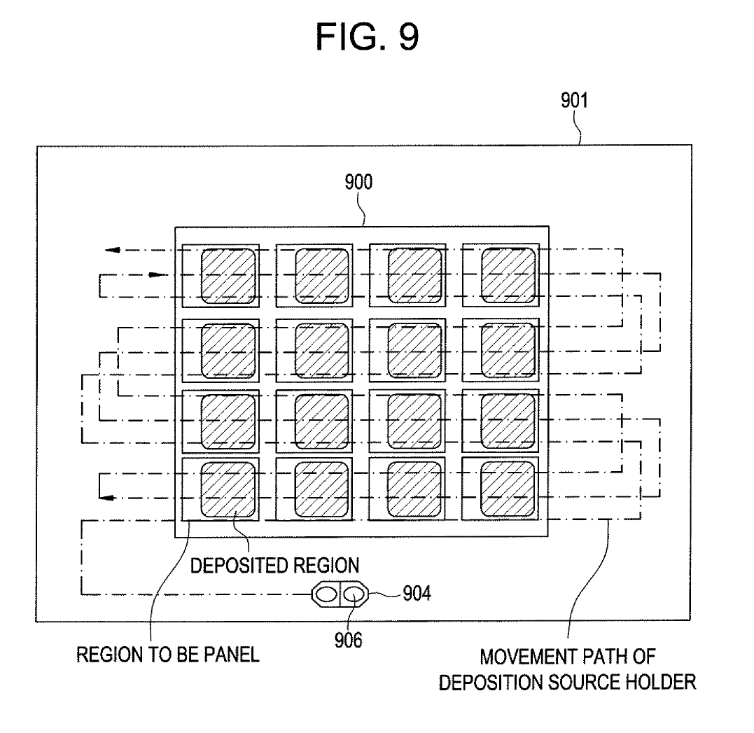

Further, when a white light-emitting element is fabricated, deposition may be conducted locally, as shown in FIG. 9. The deposition is conducted locally so that at least a region that will be a display region is contained in the region that will be a panel. Conducting the deposition locally prevents the deposition on the regions where the deposition is not required. A shutter (not shown in the figure) is used for local deposition and the deposition is conducted without a mask, by appropriately opening and closing the shutter. FIG. 9 shows an example in which gang printing is carried out. Here, the reference symbol 900 stands for a large substrate, 901—a film forming chamber, 904—a movable deposition holder, and 906—a crucible.

Further, a container (crucible 106) with the deposition material introduced therein is disposed in the deposition source holders 104a, 104b. In the example shown herein, two crucibles are disposed in one deposition source holder 104a, 104b. Another specific feature is that a film thickness meter (not shown in the figure) is provided in the disposition chamber 103. Here, monitoring with the film thickness meter is not conducted while the deposition source is moved and the frequency of replacing the film thickness meter is reduced.

When there are several containers (crucibles and deposition boats accommodating organic compounds) provided in one deposition source holder, the mounting angles of the crucibles are preferably selected so that the directions (evaporation centers) of evaporation that allow the organic compounds to be mixed together intersect in the position of the deposition object.

Further, the deposition source holder is constantly in a stand-by mode in a disposition chamber for crucibles and heating and temperature holding are carried out till the deposition rate is stabilized. A film thickness monitor (not shown in the figure) is disposed in the disposition chamber for crucibles. Once the deposition rate has stabilized, the substrate is transported into the film forming chamber 102 and alignment with a mask (not shown in the figure) is conducted. Then, the shutter is opened and the deposition holder is moved. Here, the alignment of the deposition mask or substrate is preferably confirmed by using a CCD camera (not shown in the figure). Position control may be carried out by providing respective alignment markers on the substrate and deposition mask. Once the deposition has been completed, the deposition holder is moved to the disposition chamber for crucibles and the shutter is closed. Once the shutter has been closed, the substrate is transported into the transportation chamber 102.

Further, referring to FIG. 6, a plurality of deposition holders 104a, 104b are in a stand-by mode in the disposition chamber 103, and once the material located in one deposition holder has been consumed, this deposition holder is replaced with another deposition holder and film formation can be carried out in a continuous mode by successively moving the deposition holders. While one deposition holder is moved in the film forming chamber, the emptied deposition holder can be refilled with the EL material. Using a plurality of deposition holders 104 makes it possible to form a film efficiently.

Further, only two crucibles can be set into the deposition holders 104a, 104b, but the deposition may be conducted by setting four crucibles or by setting two or only one crucible.

In accordance with the present invention, the time required for film deposition can be reduced. In prior art when the EL material was replenished, it was necessary to open the film forming chamber to atmosphere, refill the crucibles and then evacuate the chamber. Therefore, a long time was required for refilling, causing decrease in throughput.

Further, if it were possible to reduce also the adhesion to the inner walls of the film forming chamber, the maintenance frequency such as cleaning of the inner walls of the film forming chamber could be decreased.

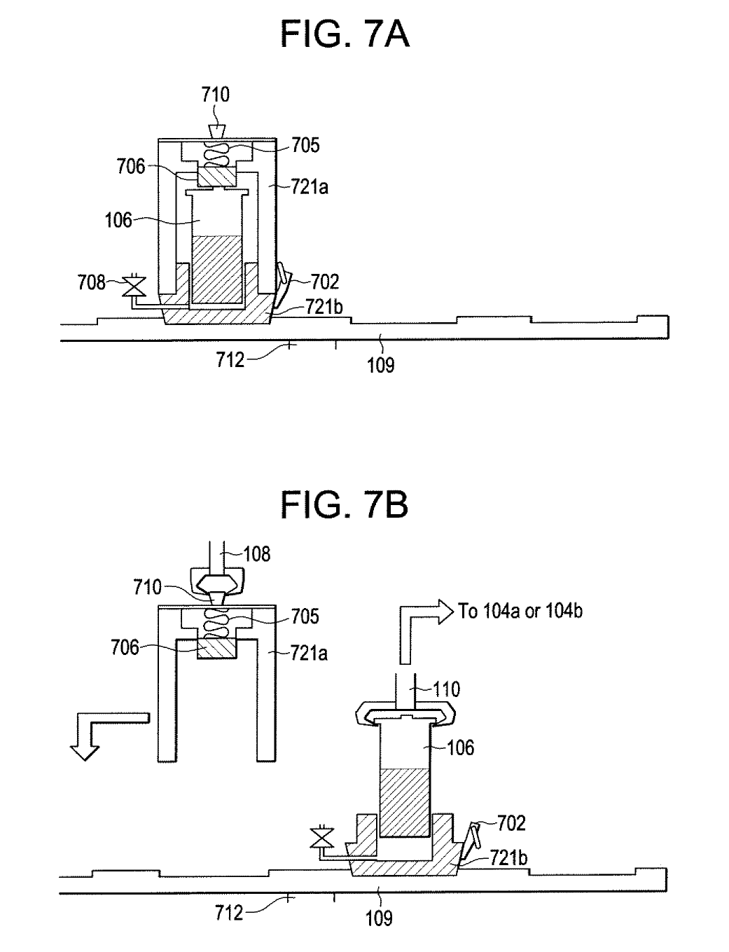

Further, disposing the crucibles 106 in the deposition holders 104a, 104b is also conducted in the disposition chamber 103b. The transportation pattern is shown in FIG. 7(A) and FIG. 7(B). Components corresponding to those shown in FIG. 6 are assigned with identical reference symbols. The crucible 106 air-tightly sealed under vacuum in a container composed of an upper part 721a and a lower part 721b is inserted from a door 112 of the disposition chamber 103. First, the inserted container is placed on a rotary stand 109 for container disposition and a latch 702 is released. Because the inside (FIG. 7(A)) is under vacuum, the removal under atmospheric pressure is impossible even if the latch 702 is released. The disposition chamber 103a is then evacuated, and a state is assumed in which the lid (upper part 721a) of the container can be removed.

The form of the transported container will be described specifically with reference to FIG. 7(A). A second container divided into an upper part (721a) used for transportation and a lower part (721b) comprises fixing means 706 for fixing a first container (crucible) provided in the upper part of the second container, a spring 705 for applying pressure to the fixing means, a gas introducing opening 708 serving as a gas path for maintaining a reduced pressure in the second container provided in the lower part of the second container, an O ring for fixing the upper container 721a and the lower container 721b, and a latch 702. A first container 106 having a purified deposition material inserted therein is disposed inside the second container. Further, the second container may be formed from a material comprising a stainless steel, and the first container 106 may be formed from a material comprising titanium.

The purified deposition material is inserted into the first container 106 by the material maker. Then, the second upper part 721a and lower part 721b are mated via the O ring, the upper container 721a and lower container 721b are fixed with the latch 702, and the first container 106 is air-tightly sealed inside the second container. Then, the pressure inside the second container is reduced via the gas introducing opening 708, the atmosphere is replaced with a nitrogen atmosphere, and the spring 705 is adjusted to fix the first container 106 with the fixing means 706. A drying agent may be disposed inside the second container. If the inside of the second container is thus maintained under vacuum or reduced pressure and nitrogen atmosphere, the adhesion of even slight amounts of oxygen or water to the deposition material can be prevented.

Then, the lid of the container is lifted and moved to a stand 107 for lid disposition by a robot 108 for lid transportation. The transportation mechanism in accordance with the present invention is not limited to the configuration in which the first container is transported while being held from above the first container 106, as described with reference to FIG. 7(B), and a configuration may be used in which it is transported while being held on the side surfaces of the first container.

Further, after the rotary stand 109 for container disposition has been rotated, only the crucible is lifted by a robot 110 for crucible transportation, while the lower part of the container is being left on the stand (FIG. 7(B)). Finally, the crucible is set into the deposition holders 104a, 104b that were waiting in the disposition chamber 103.

The disposition chamber 103 may be provided with a cleaning gas (one or several gases selected from H₂, F₂, NF₃, or O₂) and the components such as the deposition holders and shutter may be cleaned by using the cleaning gas. Further, it is also possible to clean the components such as the inner walls of the disposition chamber, deposition holder, and shutter by providing plasma generating means and generating plasma or by introducing gas ionized by plasma into the disposition chamber and to release gas with vacuum gas release means. Plasma for cleaning may be generated by exciting one or a plurality of gases selected from Ar, N₂, H₂, F₂, NF₃, or O₂.

The degree of cleaning of the film forming chamber can be thus maintained by moving the deposition holders 104a, 104 as far as the disposition chamber 103 and conducting cleaning in the disposition chamber.

Further, this example can be freely combined with Example 1. The deposition apparatus shown in FIG. 6 may be disposed in any of the film forming chambers 506W1, 506W2, 506W3 shown in FIG. 5 and the disposition chamber shown in FIG. 7 may be disposed in the disposition chambers 526a-526n shown in FIG. 5.

### Example 3

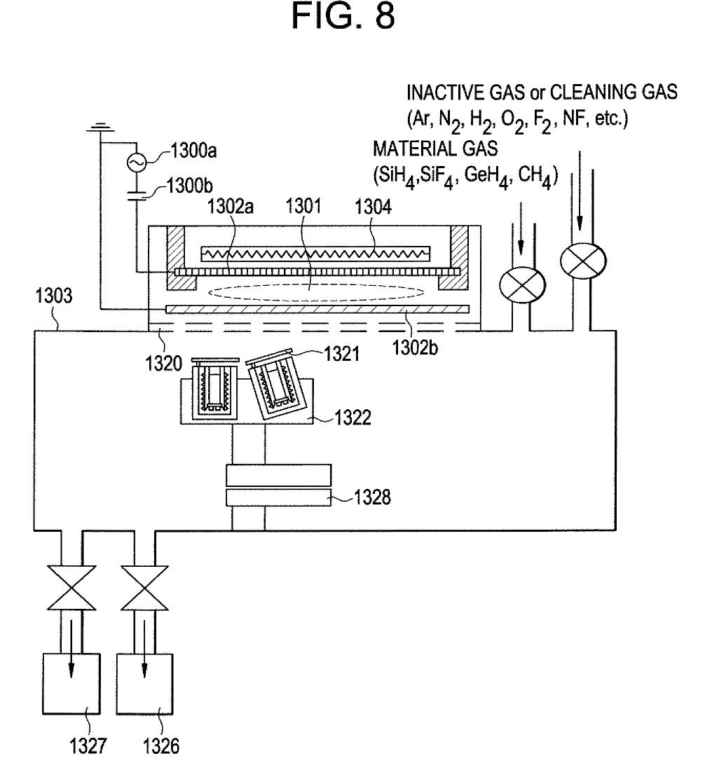

An example of the film forming chamber allowing the cleaning of the inside of the film forming chamber and the deposition mask to be conducted without opening the chamber to the atmosphere is shown hereinbelow. FIG. 8 is an example of the cross-sectional view of the film forming apparatus of the present example.

In the example shown in FIG. 8, plasma 1301 is generated between a deposition mask 1302a and an electrode 1302b connected via a high-frequency power source 1300a and a capacitor 1300b.

Referring to FIG. 8, the deposition mask 1302 fixed in a holder is installed close to a place (a place shown by a dot line in the figure) where the substrate is provided, and a deposition source holder 1322 that can conduct heating to respective different temperatures is provided therebelow. The deposition source holder 1322 can be moved with movement mechanism 1328 in the X direction, Y direction, Z direction, or θ direction which is a rotation direction.

If the organic compound located inside is heated to a sublimation temperature with heating means (typically, a resistance heating method) disposed in the deposition holder, the organic compound is gasified and deposited on the substrate surface. During deposition, the substrate shutter 1320 is moved to a position in which it does not impede the deposition. Further, a shutter 1321 that moves together with the deposition holder is also provided therein and when deposition is to be conducted, it is moved into a position in which it does not impede the deposition.

Further, a gas introduction system is provided such that during deposition, a gas composed of particles smaller than the particles of the organic compound material, that is, a gas composed of a material with a small atomic radius can be passed in a very small quantity and a material with a small atomic radius can be introduced into the organic compound film. Specific examples of gases that may be used as the gas of material with a small atomic radius include one or a plurality of gases selected from silane gases (monosilane, disilane, trisilane, and the like), SiF₄, GeH₄, GeF₄, SnH₄, or hydrocarbon gases (CH₄, C₂H₂, C₂H₄, C₆H₆, and the like). Further, a gas mixture obtained by diluting those gases with hydrogen, argon, or the like, is also included. Those gases that are introduced into the apparatus are purified to a high degree of purity with a gas purifier prior to the introduction into the apparatus. Therefore, a gas purifier has to be provided so that the gases are introduced into the deposition apparatus after purification. In this case, residual gases (oxygen, water and other impurities) contained in the gases can be removed in advance. Therefore, those impurities can be prevented from being introduced into the apparatus.

For example, when defective portions such as pinholes and short circuits occur after Si was included in the film by introducing monosilane gas during deposition and the light-emitting elements were produced, a self-healing effect can be obtained in which the Si participates in a reaction due to heat generation in those defective portions and forms an insulator with insulating properties such as SiOx and SiCx, leakage in the pinholes and short circuit portions is reduced and development of point defects (dark spots and the like) is prevented.

The components of the introduced material gas may be deposited with good efficiency on the substrate by heating the substrate with heating means such as a heater 1304 for substrate heating.

Further, radicals may be produced with plasma generation means. For example, in case of monosilane, a silicon oxide precursors such as SiHx, SiHxOy, and SiOy are formed with plasma generation means and they are deposited together with the organic compound material from the evaporation source on the substrate. Monosilane easily reacts with oxygen or moisture and the concentration of oxygen or quantity of moisture in the film forming chamber can be reduced.

A turbomolecular pump 1326 of a magnetic levitation type and a cryopump 1327 are provided as a vacuum gas release chamber to enable the introduction of a variety of gases. As a result, the attained degree of vacuum in the film forming chamber can be reduced to 10⁻⁵-10⁻⁶ Pa. After vacuum gas release with the cryopump 1327, the cryopump 1327 is stopped and deposition is conducted, while conducting vacuum gas release with the turbomolecular pump 1326 and passing the material gas at several sccm. Further, an ion plating method may be used and the deposition may be carried out, while ionizing the material gas inside the film forming chamber and causing it to adhere to the evaporated organic material.

Upon completion of deposition, the substrate is removed and cleaning is carried out for removing the deposition material that adhered to the inner walls of the film forming apparatus and jigs provided inside the film forming apparatus, without opening to the atmosphere.

Further, it is preferred that the deposition holder 1322 be moved to the disposition chamber (not shown in the figures) during cleaning.

In the course of the cleaning a wire electrode 1302b is moved to the position facing the deposition mask 1302a. Further, a gas is introduced into the film forming chamber 1303. One gas or a plurality of gases selected from Ar, H₂, F₂, NF₃, or O₂ may be used as the gas introduced into the film forming chamber 1303. Further, plasma 1301 is generated by applying high-frequency electric field to the deposition mask 1302a from a high-frequency power source 1300a and exciting the gas (Ar, H, F, NF₃, or O). Plasma 1301 is thus generated inside the film forming chamber 1303, and the deposited matter that adhered to the inner walls of the film forming chamber, a deposition-preventing shield 1305, or the deposition mask 1302 is gasified and released to the outside of the film forming chamber. With the film forming apparatus shown in FIG. 4, cleaning can be conducted without exposing the inside of the film forming chamber or deposition mask to the atmosphere during maintenance.

Here, an example was shown in which plasma was induced between the deposition mask 1302a and the electrode 1302b disposed between the mask and the deposition source holder 1306, but this example is not limiting as long as plasma generation means is employed. Further, a high-frequency powder source may be connected to the electrode 1302b and the wire electrode 1302b may be in the form of a plate-like or mesh-like electrode and it may be an electrode capable of introducing a gas as a shower head. An ECR, ICP, helicon, magnetron, two-period wave, triode, LEP, or the like, can be appropriately used as a plasma generation method.

Further, the above-described plasma cleaning may be conducted for each cycle of film forming process or can be conducted after several cycles of the film forming process have been completed.

Further, this example can be freely combined with any of Embodiments 1 to 4, Example 1, and Example 2.

### Example 4

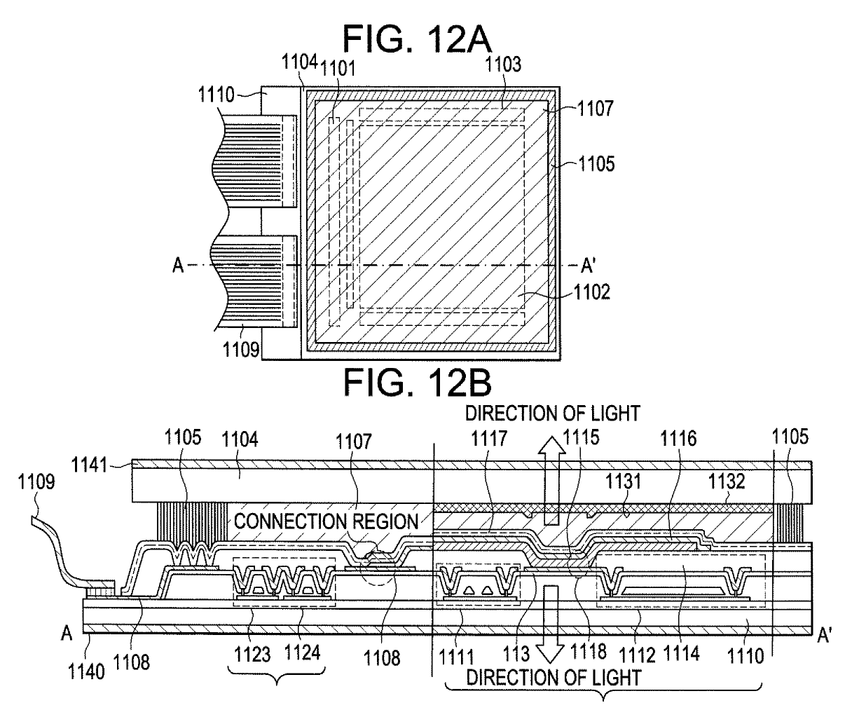

In the present working example, an example of fabricating a light-emitting device (double-side emission structure) comprising a light-emitting element employing an organic compound layer as a light-emitting layer on a substrate having an insulated surface is shown in FIG. 12.

Further. FIG. 12(A) is a top view of the light-emitting device, FIG. 12(B) is a cross-sectional view obtained by cutting FIG. 12(A) along A-A′. The reference numeral 1101 stands for a source signal line drive circuit (shown by a dot line), 1102—a pixel unit, 1103—a gate signal line drive circuit. Further, the reference numeral 1104 stands for a transparent sealing substrate and 1105—a first sealing material. The space surrounded by the first sealing material 1105 is filled with a transparent second sealing material 1107. The first sealing material 1105 comprises a gaps material for maintaining the substrate clearance.

Further, the reference numeral 1108 stands for a wiring for transmitting signals inputted into the source signal line drive circuit 1101 and gate signal line drive circuit 1103. It receives a video signal or clock signal from a FPC (flexible printed circuit) 1109 serving as an external input terminal. Here, only the FPC is shown, but a printed wiring board (PWB) may be mounted on the FPC.

The cross-sectional configuration will be explained below by using FIG. 12(B). A drive circuit and an image portion are formed on a transparent substrate 1110. Here, the source signal line drive circuit 1101 as the drive circuit and the image portion 1102 are shown.

A CMOS circuit combining a n-channel TFT 1123 and a p-channel TFT 1124 is formed as the source signal line drive circuit 1101. The TFT forming the drive circuit may be formed from a well-known CMOS circuit, PMOS circuit, or NMOS circuit. Furthermore, in the present working example, a driver-unified configuration is shown in which the drive circuit is formed on the substrate, but such a configuration is not always necessary and the drive circuit can be formed on the outside, rather than on the substrate. Further, the structure of a TFT in which a polysilicon film or amorphous silicon film serves as an active layer is not particularly limiting, and a top-gate TFT or a bottom-gate TFT may be used.

Further, the pixel portion 1102 is composed of a plurality of pixels comprising a TFT 1111 for switching, a TFT 1112 for current control, and a first electrode (anode) 113 electrically connected to the drain thereof. An n-channel TFT or a p-channel TFT may be used as the TFT 1112 for current control, but when connection is made to the anode, the p-channel TFT is preferably used. Further, it is preferred that an appropriate holding capacitance (not shown in the figure) be provided. Here, only the cross-sectional structure of one pixel of an extremely large number of pixels is shown and an example is shown in which two TFTs were used for this one pixel, but three or more TFT may be used appropriately.

In this configuration the first electrode 1113 is directly connected to the drain of TFT. Therefore, it is preferred that the lower layer of the first electrode 1113 be a material layer providing for ohmic contact with the drain composed of silicon and that the uppermost layer which is in contact with the layer containing an organic compound be a material layer with a large work function. For example, a transparent conductive film (ITO (indium oxide tin alloy), indium oxide zinc oxide alloy (In₂O₃—ZnO), zinc oxide (ZnO), and the like) is used.

Further, an insulator (called a bank, a partition wall, a separating wall, an embankment, and the like) 1114 is formed at both ends of the first electrode (anode) 1113. The insulator 1114 may be formed from an organic resin film or an insulating film containing silicon. Here, an insulator of the shape shown in FIG. 12 is formed as the insulator 1114 by using a positive-type photosensitive acrylic resin film.

A curved surface having a curvature is formed at the upper end portion or lower end portion of the insulator 1114 with the object of improving coverage. For example, when a positive-type photosensitive acryl is used as the material of the insulator 1114, it is preferred that the curved surface having a curvature radius (0.2 μm-3 μm) be provided only at the upper end portion of the insulator 1114. Furthermore, either negative-type photosensitive compositions that are made insoluble in an enchant under light or positive-type compositions that are made soluble in an etchant under light can be used as the insulator 1114.

Further, the insulator 1114 may be covered with a protective film composed of an aluminum nitride film, an aluminum nitride oxide film, a thin film containing carbon as the main component, or a silicon nitride film.

Further, a layer 1115 comprising an organic compound is selectively formed by a deposition method on the first electrode (anode) 1113. In the present working example, the layer 1115 comprising an organic compound is formed in the production apparatus described in Embodiment 2 and a uniform film thickness is obtained. Furthermore, a second electrode (cathode) 1116 is formed on the layer 1115 comprising an organic compound. A material with a low work function (Al, Ag, Li, Ca, alloys thereof, MgAg, MgIn, AlLi, CaF₂, or CaN) may be used for the cathode. Here, in order to pass the emitted light, a laminated layer of a thin metal film (MgAg: film thickness 10 nm) with a decreased film thickness and a transparent electrically conductive film (ITO (indium oxide tin oxide alloy) with a film thickness of 110 nm, an indium oxide zinc oxide alloy (In₂O₃—ZnO), zinc oxide (ZnO), and the like) is used as the second electrode (cathode) 1116. A light-emitting element 1118 composed of the first electrode (anode) 1113, the layer 1115 comprising an organic compound, and a second electrode (cathode) 1116 is thus formed. In the present working example, white emitted light is obtained by use of a layer composed of organic compounds 1115 formed by successively laminating CuPc (film thickness 20 nm), α-NPD (film thickness 30 nm), CBP (film thickness 30 nm) comprising an organometallic complex comprising platinum as a central metal (Pt (ppy)acac), BCP (film thickness 20 nm), and BCP:Li (film thickness 40 nm). This working example is an example in which the light-emitting element 1118 emits white light. Therefore, a color filter (here, for the sake of simplicity, the overcoat is not shown in the figure) composed of a coloration layer 1131 and a light-shielding layer (BM) 1132 is provided.

Further, in such double-side light-emission display device, optical films 1140, 1141 are provided in order to prevent the background from penetration and to prevent the external light reflection. A polarizing film (a polarizing plate of a high transmittance type, a thin light polarizing plate, a white light polarizing plate, a polarizing plate comprising high-performance dyes, an AR polarizing plate, and the like), a phase-difference film (a broadband 1/4λ plate, a temperature-compensated phase-difference film, a twisted phase-difference film, a phase-difference film with a wide viewing angle, a biaxially oriented phase-difference film, and the like), and a luminosity-increasing film may be used in an appropriate combination as the optical films 1140, 1141. For example, if polarizing films are used as the optical films 1140, 1141 and arranged so that the light polarization directions are orthogonal to each other, it is possible to obtain an effect of preventing the penetration of background and an effect of preventing the reflection. In this case, zones outside the portions where light is emitted and display is conducted, become black and the background can be prevented from penetrating and being seen even when the display is viewed from any side. Further, because the emitted light from the light-emitting panel passes only through one polarizing plate, it is displayed as is.

The same effects as described hereinabove can be obtained in case that even if the two polarizing films are not orthogonal, the light polarization directions are within an angle of ±45°, preferably, within ±20° with respect to each other.

With the optical films 1140, 1141, it is possible to prevent the background from penetrating, becoming visible and making it difficult to recognize the display when a person views the display from one surface.

Further, one more optical film may be added. For example, one polarizing film absorbs S waves (or P waves), but a luminosity increasing film for reflecting S waves (or P waves) onto the light-emitting elements and reproducing them may be provided between the polarizing plate and light-emitting panel. As a result, the number of P waves (or S waves) that pass through the polarizing plate increases and the increase in integral quantity of light can be obtained. In the double-side light-emitting panels, the structures of layers that pass the light from the light-emitting elements are different. Therefore, the light emission patterns (luminosity, chromaticity balance, and the like) are different and the optical films are suitable for adjusting the light emission balance on both sides. Further, in the double side light-emitting panels, the external light reflection intensities are also different. Therefore, it is preferred that the luminosity increasing film be provided between the polarizing plate and light-emitting panel on the surface with a larger reflection.

Further, a transparent protective laminated layer 1117 is formed for sealing the light-emitting element 1118. The transparent protective laminated layer 1117 is composed of a laminated layer of a first inorganic insulating film, a stress relaxation film, and a second inorganic insulating film. A silicon nitride film, silicon oxide film, silicon oxide nitride film (SiNO film (composition ratio N>O), a SiON film (composition ratio N<O)), or a thin film containing carbon as the main component (for example, a DLC film, a CN film) obtained by a sputtering method or a CVD method can be used as the first inorganic insulating film and second inorganic insulating film. Those inorganic insulating films have a strong blocking effect with respect to moisture, but if the film thickness increases, the film stresses increase and the film can be easily peeled or detached. However, stresses can be relaxed and moisture can be absorbed by sandwiching a stress relaxation film between the first inorganic insulating film and second inorganic insulating film. Further, even when fine holes (pinholes and the like) are formed for whatever reason in the first inorganic insulating film during deposition, they are filled with the stress relaxation film. Further, providing the second inorganic insulating film thereupon produces a very strong blocking effect with respect to moisture or oxygen. Further a hygroscopic material with stresses less than those in the inorganic insulating films is preferred as the stress relaxation film. Moreover, a transparent material is preferred. Further, material films comprising organic compounds such as α-NPD (4,4′-bis-[N-(naphthyl)-N-phenyl-amino]biphenyl), BCP (bathocuproine), MTDATA (4,4′,4″-tris(N-3-methylphenyl-N-phenyl-amino)triphenylamine), Alq₃ (tris-8-quinolinolatoaluminum complex) may be used as the stress relaxation film. Those material films have hygroscopicity and are almost transparent if the film thickness is small. Furthermore, because MgO, SrO₂, and SrO have hygroscopicity and light transparency and thin films thereof can be obtained by a deposition method, they can be used for the stress relaxation film. In the present example, a film formed in an atmosphere comprising nitrogen and argon by using a silicon target, that is, a silicon nitride film with a strong blocking effect with respect to moisture and impurities such as alkali metals is used as a first inorganic insulating film or second inorganic insulating film, and a thin film of Alq₃ produced by a deposition method is used as the stress relaxation film. Further, in order to pass the emitted light to the transparent protective laminated layer, the total film thickness of the transparent protective laminated layer is preferably as small as possible.

Further, the sealing substrate 1104 is pasted with a first sealing material 1105 and a second sealing material 1107 under an inactive gas atmosphere in order to seal the light-emitting element 1118. An epoxy resin is preferably used as the first sealing material 1105. Further, no specific limitation is placed on the second sealing material 1107, provided it is a material transparent to light. Typically, it is preferred that a UV-curable or thermosetting epoxy resin be used. Here, a UV epoxy resin (manufactured by Electrolight Co., 1500Clear) with high heat resistance is used. This resin has a refractive index of 1.50, a viscosity of 500 cps, a Shore D hardness of 90, a tensile strength of 3000 psi, a Tg point of 150° C., a volume resistance of 1×10¹⁵Ω·cm, and a voltage resistance of 450 V/mil. Further, filling the space between a pair of substrates with the second sealing material 1107 makes it possible to increase the transmittance of the entire body with respect to that obtained when the space between the two substrates is empty (inactive gas). Further, it is preferred that the moisture or oxygen permeability of the first sealing material 1105 and second sealing material 1107 be as low as possible.

Further, in the present working example, a plastic substrate composed of FRP (Fiberglass-Reinforced Plastics), PVF (polyvinyl fluoride), Mylar, polyesters, acryls, and the like, can be used besides a substrate or quartz glass substrate as the material constituting the sealing substrate 1104. Further, after the sealed substrate 1104 has been adhesively bonded by using the first sealing material 1105 and second sealing material 1107, sealing can be conducted with a third sealing material so as to cover the side surfaces (exposed surfaces).

Sealing the light-emitting element with the first sealing material 1105 and second sealing material 1107 in the above-described manner makes it possible to completely shield the light-emitting element from the outside and to prevent the penetration of substances, such as moisture or oxygen, that enhance the deterioration of the organic compound layer. Therefore, a light-emitting device with high reliability is obtained.

Further, when a light-emitting device of an upper-surface emission type is fabricated, the cathode is preferably a reflective metal film (chromium, titanium nitride, and the like). Furthermore, when a light-emitting device of a lower-surface emission type is fabricated, a metal film (film thickness 50 nm-200 nm) composed of Al, Ag, Li, Ca, alloys thereof, MgAg, MgIn, and AlLi is preferably used for the cathode.

This example can be freely combined with Embodiments 1 to 4 and Examples 1 to 3.

### Example 5

In this working example, an electronic device comprising two or more display devices will be explained with reference to FIG. 12. An electronic device equipped with an EL module can be created by implementing the present invention. Examples of electronic devices include video cameras, digital cameras, goggle-type displays (head-mounted displays), navigation systems, acoustic reproduction devices (car audio, audio component stereo systems, and the like), notebook personal computers, game devices, portable information terminals (mobile computers, cellular phones, portable game machines, electronic books, and the like), and image reproducing devices comprising recording medium (more specifically, devices equipped with displays capable of reproducing the recorded medium, such as Digital Versatile Disk (DVD) and displaying the image).

FIG. 12(A) is a perspective view of a notebook personal computer, FIG. 12(B) is a perspective view illustrating the folded state. The note-book personal computer comprises a body 2201, a case 2202, display portions 2203a, 2203b, a keyboard 2204, an external connection port 2205, and a pointing mouse 2206.

The notebook personal computer shown in FIG. 12(A), and FIG. 12(B) comprises the high-quality display portion 2203a mainly for full-color displaying the images and the monochromatic display portion 2203b for displaying mainly text and symbols.

Further, FIG. 12(C) is a perspective view of a mobile computer. FIG. 12(D) is a perspective view showing the back surface side. The mobile computer comprises a body 2301, display portions 2302a, 2302b, a switch 2303, a control key 2304, and an IR port 2305. It mainly comprises the high-quality display portion 2302a for full-color displaying images and the monochromatic display portion 2302b for displaying mainly text and symbols.

Further, FIG. 12(E) shows a video camera comprising a body 2601, a display portion 2602, a case 2603, an external connection port 2604, a remote control socket 2605, an image pickup unit 2606, a battery 2606, a voice input unit 2608, and a control key 2609. The display portion 2602 is a double-side light-emitting panel capable of high-quality display mainly for full-color displaying the images on one surface and monochromatically displaying mainly text and symbols on the other surface. Further, the display portion 2602 can be rotated in the mounting portion. The present invention can be employed in the display portion 2602.

Further, FIG. 12(F) is a perspective view of a cellular phone. FIG. 12(G) is a perspective view illustrating the folded state. The cellular phone comprises a body 2701, a case 2702, display portions 2703a, 2703b, a voice input unit 2704, a voice output unit 2705, a control key 2706, an external connection port 2707, and an antenna 2708.

The cellular phone shown in FIG. 12(F) and FIG. 12(G) comprises the high-quality display portion 2703a mainly for full-color displaying the images and the display portion 2703b for displaying mainly text and symbols by area colors. In this case, a color filter is used in the display portion 2703a, and an optical film serving as an area color is used for the display portion 2703b.

Further, this example can be freely combined with Embodiments 1 to 4 and Examples 1 to 4.

### Example 6

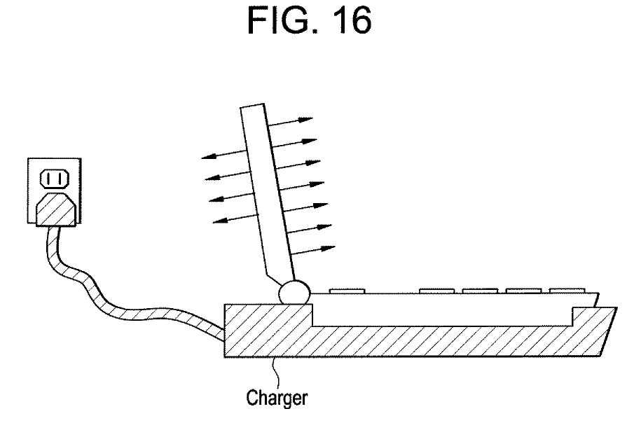

FIG. 16 is a drawing which illustrates charging of a cellular phone using the display device in accordance with the present invention. FIG. 16 illustrates a state in which the cellular phone is opened and light is emitted from both sides, but charging may be also conducted in a closed state. In display devices using light-emitting elements, the light-emitting elements generally deteriorate with time and luminosity decreases. In particular, in case of display devices in which light-emitting elements are disposed at a one-to-one ratio with pixels, because the frequency at which the pixels come on differs depending on the location, the degree of deterioration also differs depending on the location. Therefore, in the pixels with a high switching frequency, the degree of deterioration is high and image quality decreases as an image persistence effect. Accordingly, image persistence can be made inconspicuous by conducting certain display during charging, which is not a usual usage state, and switching on the pixels with a low usage frequency. A full-screen operation mode, an image with brightness inverted with respect to the standard image (stand-by screen and the like), and an image displayed by detecting pixels with a low usage frequency are examples of display contents during charging.

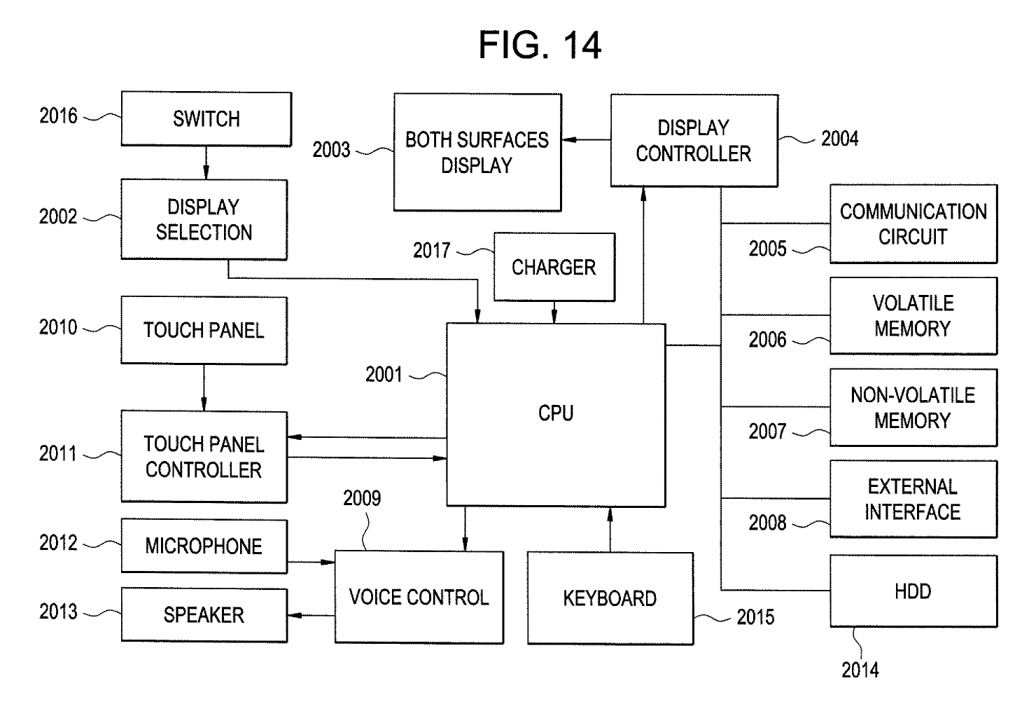

FIG. 14 is a block diagram corresponding to the drawing. A CPU 2001 obtaining charging state detection signal from a charger 2017 issues a command instructing a display controller to display a signal corresponding to the above-described and a double-side light-emitting display conducts light emission.

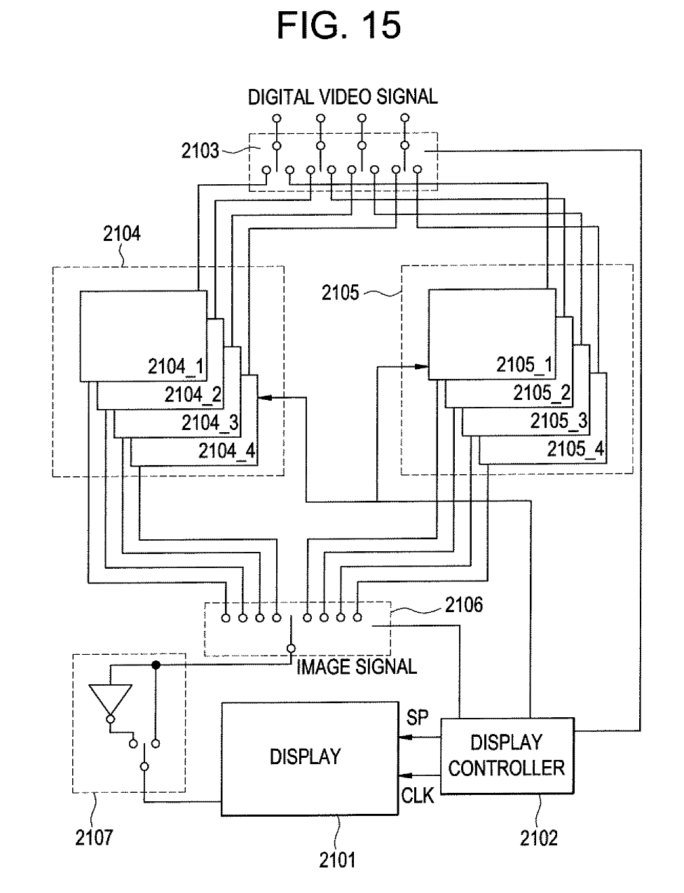

FIG. 15 illustrates an example of means for producing an image with a brightness inverted with respect to the standard image. The output of a video signal selection switch 2106 is inputted into a switch 2107 and a selection can be made whether to input the signal of a switch 2106 into a display 2101 as is or after inversion. When brightness inversion is necessary, the input may be made after inversion. This selection is conducted with the display controller. Further, in a full-screen operation mode, a fixed voltage may be inputted to the display 2101 (not shown in the figures).

The deterioration of displayed images can be thus inhibited by conducting light emission which decreases image persistence during charging.

Further, the present example can be freely combined with any of Embodiments 1 to 4 and Examples 1 to 5.

### EFFECT OF THE INVENTION

With the present invention, a large mask with a high mask accuracy can be realized for conducting selective deposition on a substrate with a large surface area. Further, the present invention makes it possible to realize a deposition apparatus allowing a uniform film thickness to be obtained over the entire substrate surface even on substrates with a large surface area.

What is claimed is:

1. A method for manufacturing a light-emitting device comprising:
providing a first container having a first opening accommodating a first deposition material and a second container having a second opening accommodating a second deposition material in a deposition source holder;
heating the first container and the second container; and
co-depositing an EL layer comprising the first deposition material and the second deposition material over a substrate while mixing the first deposition material and the second deposition material,
wherein the first opening and the second opening are provided in different directions so that a deposition center of the first deposition material and a deposition center of the second deposition material over the substrate are adjusted to be same.

2. The method for manufacturing the light-emitting device according to claim 1, wherein the substrate is fixed during the co-depositing step.

3. The method for manufacturing the light-emitting device according to claim 1, wherein co-depositing step is conducted while homogeneously mixing the first deposition material and the second deposition material.

4. The method for manufacturing the light-emitting device according to claim 1, wherein distance between the substrate and the deposition source holder is 30 cm or less.

5. A method for manufacturing a light-emitting device comprising:
providing a first container having a first opening accommodating a first deposition material and a second container having a second opening accommodating a second deposition material in a deposition source holder;
heating the first container by a first heater and the second container by a second heater; and
co-depositing an EL layer comprising the first deposition material and the second deposition material over a substrate while mixing the first deposition material and the second deposition material,
wherein the first opening and the second opening are provided in different directions so that a deposition center of the first deposition material and a deposition center of the second deposition material over the substrate are adjusted to be same.

6. The method for manufacturing the light-emitting device according to claim 5, wherein the substrate is fixed during the co-depositing step.

7. The method for manufacturing the light-emitting device according to claim 5, wherein co-depositing step is conducted while homogeneously mixing the first deposition material and the second deposition material.

8. The method for manufacturing the light-emitting device according to claim 5, wherein distance between the substrate and the deposition source holder is 30 cm or less.
